(19) United States
(12) Patent Application Publication
(10) Pub. No.: US 2025/0370522 A1
(43) Pub. Date: Dec. 4, 2025

(54) Redundant Parallel Power Tray for Rack-Mounted Equipment

(71) Applicant: William Pachoud, Boulder, CO (US)

(72) Inventors: William Pachoud, Boulder, CO (US); Steven Chapel, Boulder, CO (US)

(73) Assignee: Zonit Structured Solutions LLC, Boulder, CO (US)

(21) Appl. No.: 19/209,665

(22) Filed: May 15, 2025

Related U.S. Application Data
(60) Provisional application No. 63/648,080, filed on May 15, 2024.
(60) Provisional application No. 63/648,354, filed on May 16, 2024.
(60) Provisional application No. 63/686,114, filed on Aug. 22, 2024.
(60) Provisional application No. 63/686,661, filed on Aug. 23, 2024.

(51) Int. Cl. G06F 1/26; G06F 1/18; G06F 1/20; H05K 7/20

(52) U.S. Cl. CPC G06F 1/263; G06F 1/189; G06F 1/206; H05K 7/20727; H05K 7/20836

(57) ABSTRACT

Systems, methods, and associated functionality are provided for supplying power to high-power IT devices, such as artificial intelligence servers. In one embodiment, a piece of electronic equipment includes multiple internal power supplies, each internal power supply being associated with a power port for receiving power from an external source. An automatic transfer switching system, separate from the piece of electronic equipment, is provided for receiving input power from first and second power sources and selectively providing output power to a load via one or more output ports. Power cords connect a plurality of the power ports of the piece of electronic equipment to the one or more output ports of the automatic transfer switching system.

### CROSS REFERENCE TO RELATED APPLICATIONS

This application is a non-provisional of U.S. Provisional Patent Application No. 63/648,080, entitled, “POWER SUPPLY SYSTEM FOR HIGH-POWER IT DEVICES,” filed on May 15, 2024, and a non-provisional of U.S. Provisional Patent Application No. 63/648,354, entitled, “POWER SUPPLY SYSTEM FOR HIGH-POWER IT DEVICES,” filed on May 16, 2024, and a non-provisional of U.S. Provisional Patent Application No. 63/686,114, entitled, “RETRACTABLE POWER TRAY FOR RACK-MOUNTED EQUIPMENT,” filed Aug. 22, 2024, and a non-provisional of U.S. Provisional Patent Application No. 63/686,661, entitled, “REDUNDANT PARALLEL POWER TRAY FOR RACK-MOUNTED EQUIPMENT,” filed Aug. 23, 2024. The contents of the above-noted applications are incorporated by reference herein as if set forth in full and priority to this application is claimed to the full extent allowable under U.S. law and regulations.

### FIELD OF INVENTION

The present invention relates to systems and associated functionality for supplying power to high-power IT or other devices, for example, devices including multiple internal redundant or non-redundant (AC or DC) power sources such as artificial intelligence servers or equipment with high power requirements.

### BACKGROUND OF THE INVENTION

One or more automatic transfer switch (ATS) units can be used to power an IT device (such as a server for example) with one or more power supplies. Mission critical and high-power load IT devices often use multiple power supplies to input the required power levels and to add power redundancy. There are two commonly used configurations. The first is a “symmetric” power supply design where the number of internal power supplies in the device are always an even integer number such as 1+1, 2+2, N+N, etc. and that only half of the power supplies are needed to keep the device running and running at maximum performance levels. The symmetric design has the advantage that if two power sources A and B are available, which is typical of data centers and other mission critical facilities, only one power source is required for the IT device to run and run at maximum performance. This allows either the A or B power source to be taken off-line for maintenance or even fail without affecting the uptime or performance levels of the IT device. A disadvantage of this design is that it uses more power supplies than are needed to power the device and therefore wastes energy, because every power supply has loss factors, such as the energy required to run the power supply itself and the efficiency level at which the power supply runs. A further issue is the disposal of the power supplies upon retirement of the IT device. Electronic waste is a serious environmental issue and takes time, energy and attention to deal with. The symmetric power supply design adds to this burden.

Another power supply design is the “asymmetric” method. In this design, the number of power supplies needed to either keep the device running and/or keep the device running at maximum performance levels is more than half of the number of power supplies. Note that the number of power supplies needed to keep the device running versus allowing it to run at maximum performance levels can and do vary, because it makes sense for device designers to at a minimum ensure that the device still operates with half or less of its power supplies, even if it cannot operate at maximum performance. Typical configurations are 2+1, 3+1, 4+1, 5+1, N+1, etc. This is the most efficient method, because there is effectively only one spare power supply. This minimizes both the number of power supplies and the difference between their load levels when all power supplies are available versus when one has failed or is otherwise unavailable. This allows the power supplies to be configured and run at or closest to the load levels that are optimum for power supply efficiency.

Other variants of the asymmetric power supply design are possible with additional numbers of spare power supplies, such as 3+2, 5+2, N+2, N+3, N+X where N>X and so on, but all of the asymmetric power supply designs share the characteristic that more than half the power supplies must be active to keep the device running and/or running at maximum performance levels. It is possible to design an IT or other device with internal power switching methods to turn power supplies on and off as needed, and/or connect and disconnect them to loads but this adds significant complexity, cost and can lower reliability so it is rarely done.

### SUMMARY OF THE INVENTION

The present invention relates to systems and associated functionality for supplying power to high-power IT and/or other devices, for example, devices including multiple internal redundant or non-redundant (AC or DC) power sources (one form of which is called a Power Supply Unit, or PSU) such as Artificial Intelligence (AI) servers. In many cases, these devices are expensive, high-value devices. It is therefore important to ensure that the devices continuously maintain an adequate power supply for full functionality. Accordingly, it is important that the device power supplies are provided with reliable power from redundant, fail-safe power sources. It is also important that such power is provided efficiently to reduce costs, reduce power consumption, and provide an environmentally friendly or green solution.

In one aspect of the invention, a method for supplying power to electronic equipment is provided. The method provides a piece of electronic equipment including multiple internal power supplies, each internal power supply being associated with a power port for receiving power from an external source. An automatic transfer switching system is provided, separate from the piece of electronic equipment, for receiving input power from first and second power sources and selectively providing output power to a load via one or more output ports. A plurality of the power ports of the piece of electronic equipment are connected, via power cords, to the one or more output ports of the automatic transfer switching system.

In another aspect of the invention, a system for supplying power to electronic equipment is provided. The system includes a piece of electronic equipment including multiple internal power supplies, each internal power supply being associated with a power port for receiving power from an external source. An automatic transfer switching system, separate from the piece of electronic equipment, is provided for receiving input power from first and second power sources and selectively providing output power to a load via one or more output ports. Power cords connect a plurality of the power ports of the piece of electronic equipment to the one or more output ports of the automatic transfer switching system.

In a further aspect of the invention, a method for supplying power to electronic equipment is provided. The method provides a piece of electronic equipment including multiple internal power supplies, each internal power supply being associated with a power port for receiving power from an external source, the piece of equipment being disposed in an equipment rack. An air-based cooling system is provided for the equipment rack, the air-based cooling system being free of any liquid coolants at the equipment rack. The air-based cooling system is operated to cool the piece of equipment in the equipment rack.

In another aspect of the invention, a system for supplying power to electronic equipment is provided. The system is provided with a piece of electronic equipment including multiple internal power supplies, each internal power supply being associated with a power port for receiving power from an external source, the piece of equipment being disposed in an equipment rack. An air-based cooling system is provided for the equipment rack, the air-based cooling system being free of any liquid coolants at the equipment rack. The air-based cooling system is operative to cool the piece of equipment in the equipment rack.

In a further aspect of the invention, a method for supplying power to electronic equipment is provided. The method provides an automatic transfer switching system comprising multiple automatic transfer switches, each of the multiple automatic transfer switches being operative for receiving input power from the first and second power sources and selectively providing output power to a load via one or more output ports. The multiple automatic transfer switches are mounted on an upper power tray. The upper power tray is movably mounted in a lower mounting tray.

In still another aspect of the invention, a system is provided for supplying power to electronic equipment. The system includes an automatic transfer switching system comprising multiple automatic transfer switches, each of the multiple automatic transfer switches being operative for receiving input power from the first and second power sources and selectively providing output power to a load via one or more output ports. The multiple automatic transfer switches are mounted on an upper power tray. The upper power tray is moveably mounted in a lower mounting tray.

In a further aspect of the invention, a method is provided for supplying power to electronic equipment. The method provides a piece of electronic equipment including multiple internal power supplies, each internal power supply being associated with a power port for receiving power from an external source. The method further provides multiple power distribution system devices. The piece of electronic equipment is interconnected with the multiple power distribution devices such that the multiple power distribution devices are associated with a first power port of the multiple power ports.

In another aspect of the invention, a system for supplying power to electronic equipment is provided. The system includes a piece of electronic equipment including multiple internal power supplies, each internal power supply being associated with a power port for receiving power from an external source. The system further includes multiple power distribution system devices. The piece of electronic equipment and the multiple power distribution devices are interconnected such that the multiple power distribution devices are associated with a first power port of the multiple power ports.

In yet another aspect of the invention, a method is provided for supplying power to electronic equipment. The method includes providing a piece of electronic equipment including multiple internal power supplies, each internal power supply being associated with a power port for receiving power from an external source. The method further includes providing multiple automatic transfer switches. The piece of electronic equipment and the multiple automatic transfer switches are interconnected such that the multiple automatic transfer switches are associated with a first power port of the multiple power ports.

In a further aspect of the invention, a system for supplying power to electronic equipment is provided. The system includes a piece of electronic equipment including multiple internal power supplies, each internal power supply being associated with a power port for receiving power from an external source. The system further includes multiple automatic transfer switches. The piece of electronic equipment and the multiple automatic transfer switches are interconnected such that the multiple automatic transfer switches are associated with a first power port of the multiple power ports.

In addition to the various aspects and embodiments described above, further aspects of the invention will become apparent by reference to the drawings and by study of the following description. Reference is made to the accompanying drawings which illustrate how the invention can be practiced through specific, non-limiting examples. It is understood that other examples can be used, and structural changes can be made without departing from the scope of the invention.

### BRIEF DESCRIPTION OF THE DRAWINGS

For a more complete understanding of the present invention and further advantages thereof, reference is now made to the following detailed description taken in conjunction with the drawings in which:

FIG. 1 depicts a schematic diagram of a system for supplying power to electronic equipment in accordance with the present invention.

FIG. 2 depicts one embodiment of a power supply system using one Z-ATS industrial unit per power cord of a device.

FIG. 3 depicts an embodiment of a power tray as the same can be used with the power supply system of FIG. 2.

FIG. 4A depicts one configuration of a power supply system incorporating trays of ATSs.

FIG. 4B depicts another configuration of a power supply system incorporating trays of ATSs.

FIG. 4C depicts an example of a layout of a rack for a plurality of rack units in accordance with the present technology.

FIG. 5 depicts an embodiment of an alternative cooling system, in accordance with the present technology.

FIG. 6 depicts an embodiment of adjacent ATSs that are interconnected via a connector extending between T-slots of adjacent ATS units4.

FIG. 7 depicts a schematic of one configuration of a plurality of power supplies associated with an AI system.

FIG. 8 depicts one example of a layout of a rack that is powered by a Zonit Double-Shot power distribution device.

FIG. 8b depicts another example of a layout of a rack that is powered by a Zonit Double-Shot power distribution device.

FIG. 9 depicts a Z-PDS power distribution system unit that has had multiple ATS units incorporated into its enclosure.

FIG. 10 depicts a front, elevation view of an XE9680 unit that may be incorporated with the present technology.

FIG. 11 depicts a rear, elevation view of the XE9680 unit of FIG. 10.

FIG. 12 depicts a bottom, plan view of the XE9680 unit of FIG. 10.

FIG. 13A depicts a perspective view of the one embodiment of a power tray of the present technology as the same is in a retracted position.

FIG. 13B depicts a perspective view of the power tray of FIG. 13A as the same is in an extended position.

FIG. 13C depicts a schematic view of the power tray of FIG. 13A.

FIG. 14A depicts a top perspective view of one embodiment of a small form factor PSU that may be incorporated with the present technology.

FIG. 14B depicts a side perspective view of the small form factor PSU Of FIG. 14A.

FIG. 14C depicts a side elevation view of the small form factor PSU Of FIG. 14A.

FIG. 15 depicts various views of one embodiment of an IEC C22 inlet receptacle that may be used in PSUs of the present technology.

FIG. 16 depicts perspective views of single and double inputs utilizing C-20 inlets, as the same may be incorporated with the present technology

FIG. 16A depicts a combined PSU device that may be incorporated with the present technology.

FIG. 16B depicts a PSU-ATS using dual locking power input receptacles, which have the necessary small footprint, amperage and voltage ratings required to build the PSU-ATS in the same form-factor as the PSU that it would replace.

FIG. 17 depicts one embodiment of an AC side ATS with two plugs, A and B, and an internal electrical transfer means to select either the A side or the B side and route the AC power from one of those inputs to the output socket.

FIG. 18 depicts a graph comparing a percentage of rated device voltage with a time duration (in seconds) in cycles at 60 Hz.

FIG. 19 depicts one embodiment of an input rectifier section of a power supply, such as depicted in FIG. 17, having two rectifier bridges that have the DC outputs of each connected together and delivering rectified AC to a filter capacitor.

FIG. 20 [Not used]

FIG. 21 depicts a synchogram that demonstrates the time (horizontal axis) to voltage (vertical axis) relationship of the three phases in a common three phase power delivery location.

FIG. 22 depicts a synchogram that demonstrates “split phase,” where each AC phase is 180° apart from each other.

FIG. 23 depicts rectifiers that are wired together as a dual rectifier section, demonstrating that, when A phase is at Time 1, the voltage on the line side of that plug is positive 339 volts and current is flowing to the output and the filter capacitor via D2, while the B side voltage on the line side is negative 339 volts and current is flowing to the load and the filter capacitor via D5.

FIG. 24 depicts another voltage increasing problem but for the application bridging two phases of a three-phase system (120°).

FIG. 25 depicts an embodiment of a dual input and rectifier section which has added DC on/off switches in line with the DC power paths.

FIG. 26 depicts a synchogram showing the selection of phases A and B in a three-phase system (120°) for use as the two inputs to a dual input power supply.

FIG. 27 depicts a block diagram of the inside of a controller section and the location of the analog buffer/isolation components.

FIG. 28 depicts the resulting voltage output delivered to the filter capacitor as the A and B sides are alternately connected to the capacitor.

FIG. 29 depicts one embodiment of a “Split Phase” which is 180° separated with respect to voltage polarity.

FIG. 30 depicts that, when rectified, the two input sources A and B are exactly matched but the polarity is reversed with respect to the phase to phase, and thus the voltages sum if they are routed through the common connected rectifier.

FIG. 31 depicts one embodiment of a controller section according to the present technology, which has an added logic layer.

FIG. 32 depicts one set of results of switching between the inverted versus non-inverted sources of the A side, then the B side every 160 ms.

FIG. 33 [Not used]

FIG. 34 depicts several embodiments of circuit breakers, such as single and multi-pole circuit breakers. with components as the same may be used with the present technology.

FIG. 35 depicts one embodiment of an example mechanism, which is similar to a matchlock pistol, that opens the contacts when the power or voltage is out of specified limits.

FIG. 36 depicts perspective views of 1200V MCZ receptacles that may be used with the present technology.

FIG. 37 [Not used]

FIG. 38 [Not used]

FIG. 39 depicts one embodiment of an apparatus that operates with either 600V or 1200V power sources and three phase utility power is delivered to the site at preferred utility voltages for the region and stepped down to standard 600 Volt AC three phase with split single phase voltage outputs.

FIG. 40 depicts the typical delivery of utility power to the end use equipment.

FIG. 41 depicts how incoming AC power is typically delivered via a step-down transformer.

FIG. 42 depicts the effect of combining two transformers, such as depicted in FIG. 41, into one transformer.

FIG. 43 depicts one embodiment of the manner in which an end use power supply arrangement takes advantage of aspects of the present technology.

FIG. 44 depicts one embodiment of a connector of the present technology that can have an integrated safety disconnect system that utilizes four conductors, where the phase is 180 degrees different from the phase between the ground and the neutral.

FIG. 45 depicts another embodiment of the connector depicted in FIG. 44.

FIG. 46 depicts a three phase sub-group of high voltage connectors on a single section of a power distribution unit.

FIG. 47 depicts one embodiment of a vertical PDU with nine individual circuits, with three 60 A feeds, each powering a group of three outlet receptacles.

FIG. 48 depicts a cross-sectional side view of the general mechanical configuration of one embodiment of a circuit breaker that can integrate with the receptacle of the present technology.

FIG. 49 depicts a front cross section view of the circuit breaker assembly of FIG. 48, as observed from the electrical connector side.

FIG. 50 depicts a schematic of one embodiment of the electrical components associated with the detection of the amount of current in the circuit breaker path, and the actuation of the disconnect mechanism.

FIG. 51 depicts the moment of transition from the moment of having detected a current overload and before the circuit breaker disconnects the contacts.

FIG. 52 depicts the point where the circuit breaker moving contact arm is in motion and the tip of the sear is rounding the end of the pawl roller wheel.

FIG. 53 depicts the continuation of the disconnect action depicted in FIG. 52.

FIG. 54 depicts the final resting position for the contacts after the complete opening of the circuit breaker.

FIG. 55 depicts one embodiment of the desired maximum power delivery available with the present technology as it fits in the vertical height limitation of approximately 80″ in a computer rack.

FIG. 56 depicts one embodiment of a power distribution unit, which can be either horizontally or vertically mounted in an equipment rack.

FIG. 57 depicts one embodiment of an example of how three vertical zero U-mount 216 KVA3 Split 3 Phase 60 A 600 V module with nine receptacles could appear in an 80″ computer rack.

FIG. 58 depicts one embodiment of how a horizontal configured 216 KVA3 Split 3 Phase 60 A 600 V module with nine receptacles might appear in a conventional 80″ Computer Room Equipment Rack.

### DETAILED DESCRIPTION

In the following description, the invention is set forth with respect to various systems, components and processes for use in a data center environment. It will be appreciated that various aspects of the invention are applicable in other contexts. Accordingly, the specific structure and functionality set forth below should be understood as exemplifying the invention and not by way of limitation. Moreover, for convenience of reference, various systems, components and methodology are identified by the Zonit trademark. The Zonit trademark is owned by Zonit Structural Solutions, LLC, the assignee of the present invention.

A power supply system is described below for supplying power to high-power IT devices, such as AI servers. The system builds upon and leverages a number of technologies of Zonit Structured Solutions (Zonit) that are described in the following documents (“incorporated documents”).
1. U.S. Pat. No. 11,664,677, entitled “Intelligent Automatic Transfer Switch Module” (ATS Case).
2. U.S. patent application Ser. No. 16/905,822, entitled “Management Module, Z-Strip, and Mini-ATS Systems and Related Components” (Management Module Case).
3. U.S. Pat. No. 10,209,727, entitled “Power Distribution Systems and Methodology,” (the Power Methodology case”).
4. U.S. Pat. No. 11,985,790, entitled “Modular Data Center Cooling.”
5. U.S. Pat. No. 6,628,009, entitled “Load Balanced Polyphase Power Distributing System.”
6. U.S. patent application Ser. No. 18/207,032, entitled “Power Distribution Using Hydra Cable Systems” (“Power Distribution case”).
7. U.S. Pat. No. 11,211,216, entitled “Accelerated Motion Relay.”
8. U.S. patent application Ser. No. 16/817,504, entitled “Relay Conditioning and Power Surge Control” (“Z-Crush case”).
9. U.S. Pat. No. 10,516,237, entitled “Frictional Locking Receptacle with Programmable Release” (“Programmable Release case”).
10. U.S. Pat. No. 11,439,034, entitled “Universal Equipment Mounting System” (“UCAB case”).

The use of a power supply system including one or multiple automatic transfer switches to power one or more IT devices and other suitable loads has been previously described in the incorporated documents. We can now expand upon a number of particular instantiations that do this for a variety of purposes and the benefits of doing so.

We now turn to the advantages of using one or more ATS units to power these types of IT devices and other suitable loads. It should be noted that these ATS units can either be built to switch AC power or DC input power. Therefore, the devices that they are incorporated into can be either AC or DC with appropriate electrical connectors. It should also be noted that the ATS units can be combined with Power Supply Units (defined herein as a PSU-ATS). This invention is described in the incorporated documents including, for example, in the Power Distribution Case which is incorporated by reference. One instantiation would switch AC input power with a single DC output. This can be done in two ways, by switching the AC power inputs and then converting it to a DC power output or by converting the two AC input sources to DC separately and then switching their DC power outputs so that only one of the DC outputs is active at any time. To do the second method with two different polyphase AC phases as input, requires that the DC switching be carefully controlled to prevent significant DC voltage rises in the DC output.

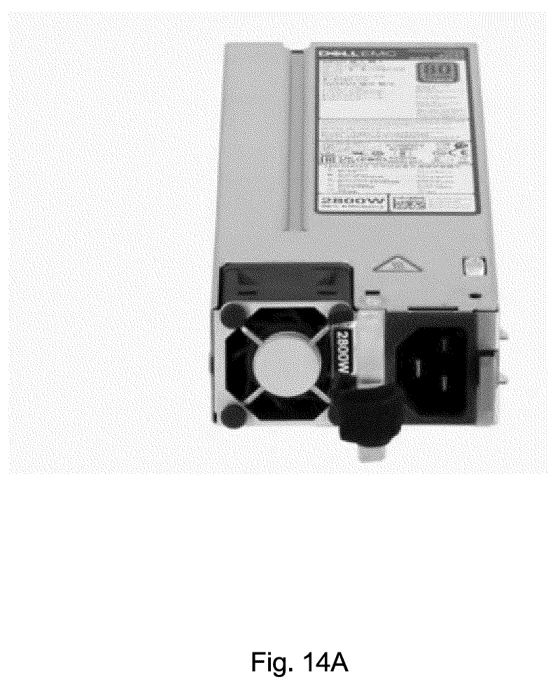

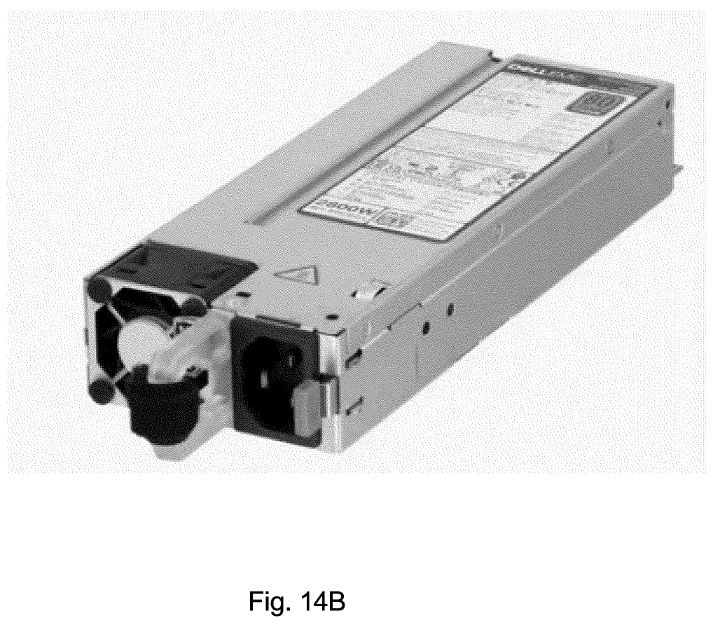

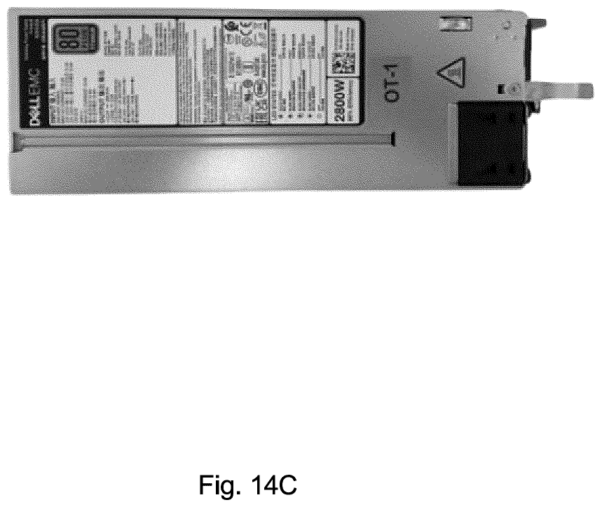

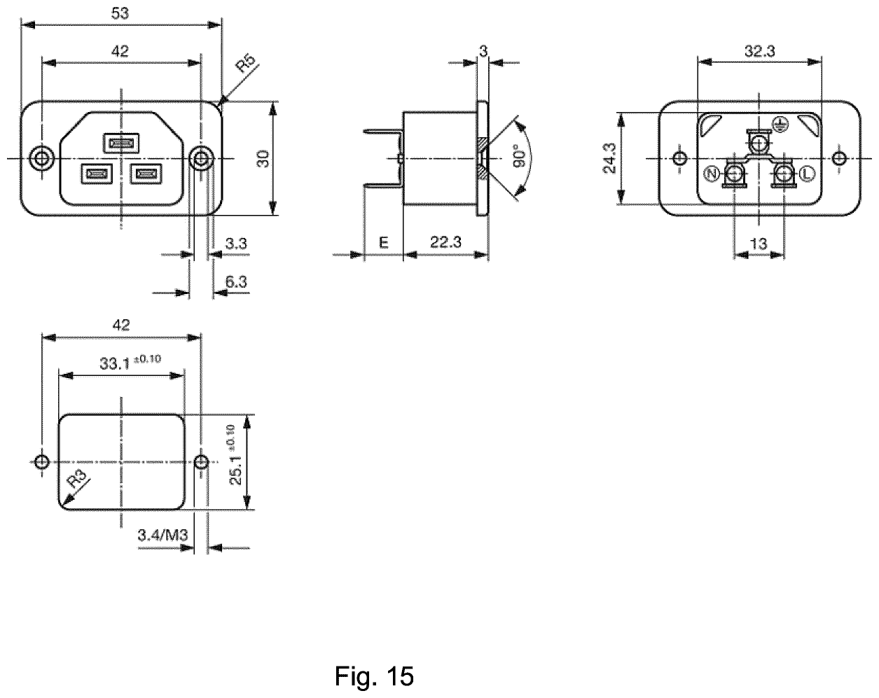

The great majority of the servers and IT devices in the world are built in 1U and 2U form-factors, which constrains their PSU modules to be small. Zonit has invented electrical small-form factor connectors and small form-factor ATS units which together enable the design of combined PSU-ATS devices that can fit into the form-factors required by 1U and 2U servers for their PSU devices. FIGS. 14A-14C show some typical PSUs of this form factor. Note the dimensions of the IEC C22 inlet receptacle used in the PSU as shown in FIG. 15, which can give the size of the PSU via comparison of the size ratios. Additionally, depending on the specific power capacity of the PSU device, one instantiation of the invention could be a PSU-ATS device as described in this and the incorporated documents that is a drop-in replacement for one or more PSU devices, thus adding a redundant power source to an existing IT device that is either currently selling and/or deployed in the field. Many PSU designs are modular and field replaceable by end-users, so they could potentially upgrade their own IT or other devices. This is a significant operational reliability improvement and maintenance convenience for end-users, which could have a very desirable price point and thus is very valuable. Inventions to build PSU-ATS units or when combined enable that to be done are contained in this and the incorporated documents including, for example, in the Power Distribution Case.

It should be noted that by combining traditional PSUs and PSU-ATS power supplies, a variety of desirable power supply methods with a range of characteristics and cost points become feasible. Therefore the ability to build drop-in PSU-ATS replacement units and/or PSUs with matching PSU-ATS form-factors is desirable. An example would be to use 4 PSU-ATS units with 2 PSU only units in a device that was built with an N+2 PSU architecture. This example would provide full A-B power source 100% device performance level redundancy. This would be a potentially cost-effective way to upgrade that device using only four PSU-ATS units versus six, resulting in less cost and potential electronic waste. A key point in the example is that only a sufficient number of PSU-ATS units to ensure that the number of operational power supplies when either A or B input power is not available are equal to or greater than N are required. One skilled in the art can appreciate the novel combinations of power supply architecture, PSU units and PSU-ATS units that are possible and the range of economic, operational and environmental characteristics that this invention would give a designer to choose from.

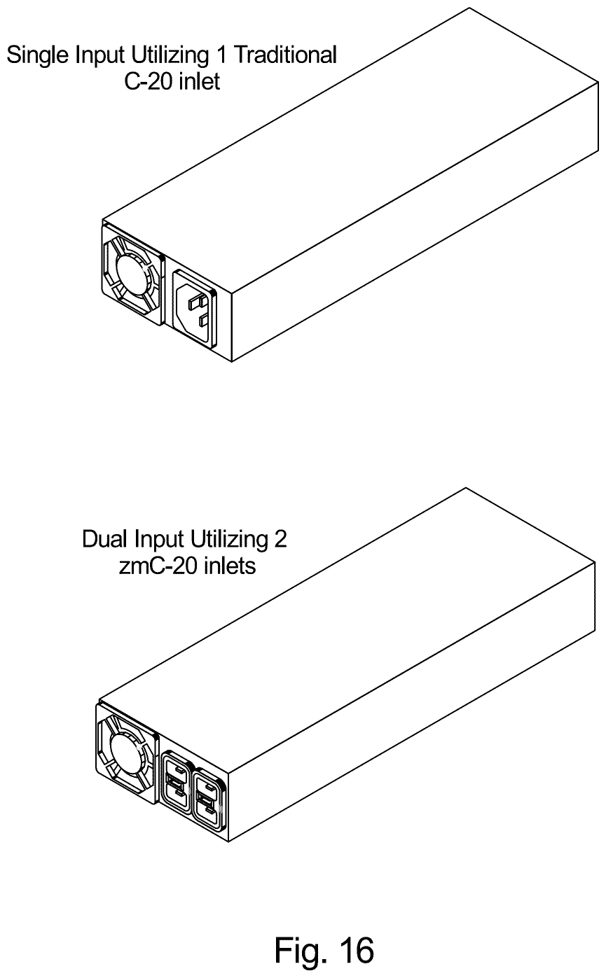

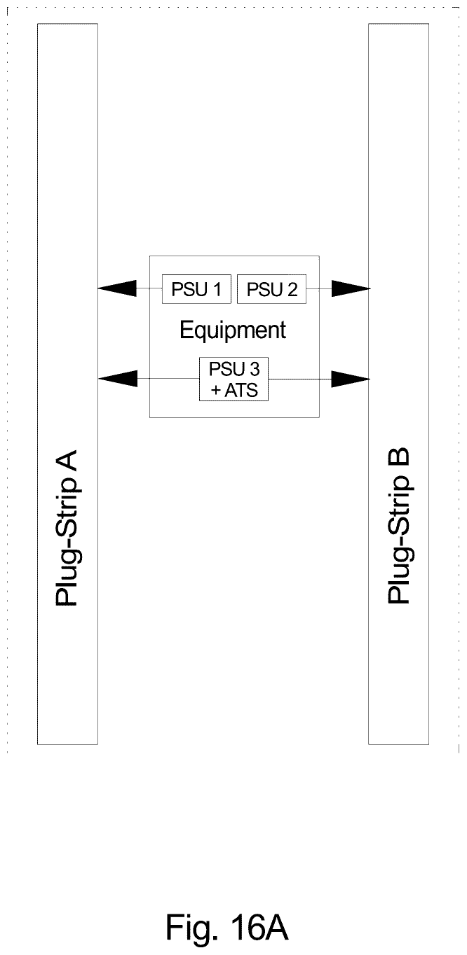

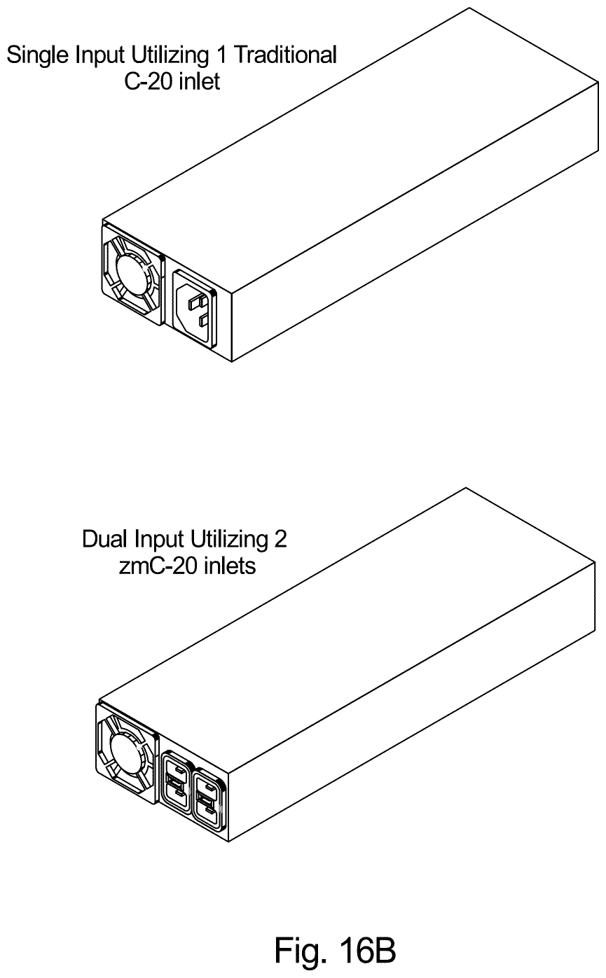

One possible instantiation of a combined PSU device is shown in FIG. 16A. FIGS. 14A-C show a typical PSU with a form-factor suitable for 1-2 U IT devices. FIG. 16B shows a PSU-ATS of the same form-factor using the Zonit zmC19 dual locking power input receptacles, (any other suitable receptacle type could be used) which have the necessary small footprint and amperage and voltage ratings required (which is novel in this application) to build the PSU-ATS in the same form-factor as the PSU that it would replace. This instantiation of the invention being described is a Dual Input AC to DC Power Supply. It adds ATS functionality to existing AC to DC power supply unit designs, which are often but not always switch mode type power supplies. This instantiation of the invention integrates two AC power source inputs into one power supply AC to DC converter.

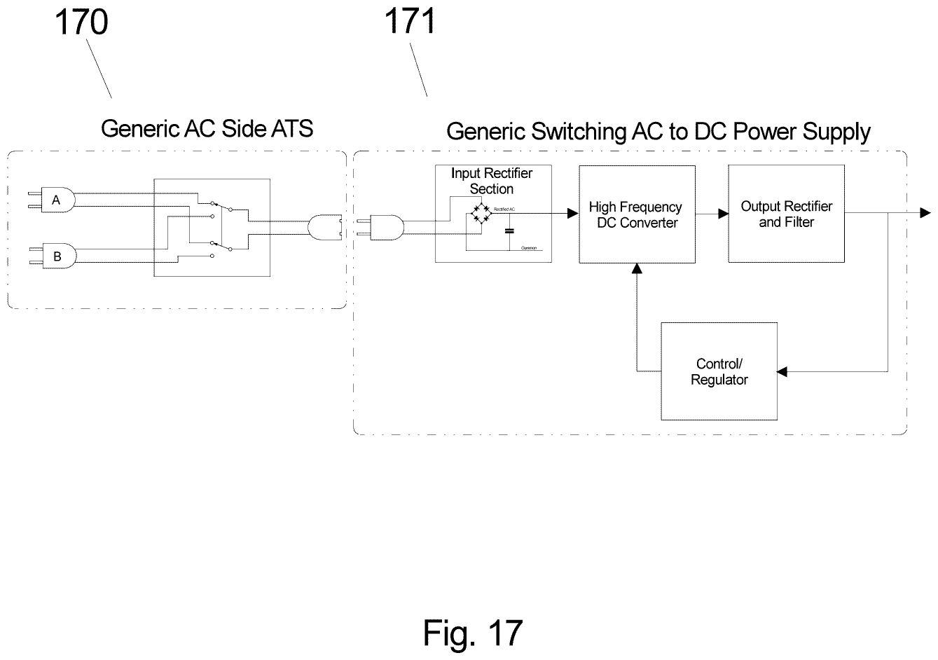

This functionality is currently typically accomplished by placing an AC switch in line before the AC to DC power supply. That AC switch is generally referred to as an Automatic Transfer Switch, or ATS. Now refer to FIG. 17. The generic AC side ATS (170) is shown with two plugs, A and B, and an internal electrical transfer means is supplied to select either the A side or the B side and route the AC power from one of those inputs to the output socket. The output socket delivers automatically transferred power to the input to a generic AC to DC power supply (171).

The intent is to increase the availability of the DC power supply for a variety of reasons, but usually it involves uninterrupted computation, or operation of electrically powered devices. Two independent AC power sources are generally delivered to this arrangement of power delivery components. The disadvantage of this method is that an external box with the ATS in it is necessary and that takes up valuable space, particularly in data center racks and enclosures, as previously discussed.

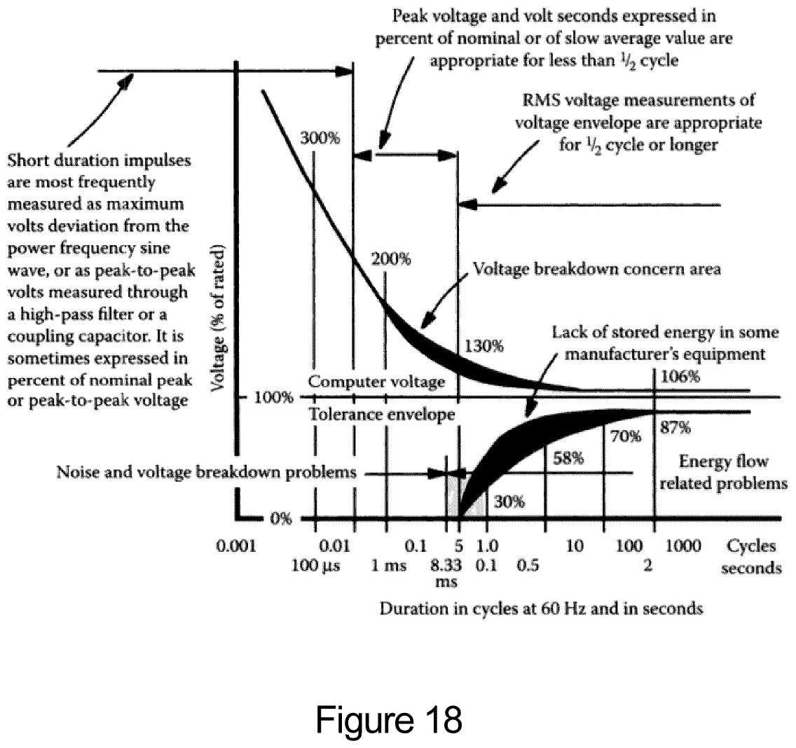

The invention allows the elements of the external ATS to be integrated into the DC power supply assembly. However, it requires that a significant volume of materials be placed inside of the AC to DC power supply enclosure, potentially increasing the overall size of that power supply unit appreciably. It also remains difficult to switch the AC sources quickly and safely. There are multiple safety regulations that involve distance through insulation, electrical source isolation and also the requirement that sufficient cooling be provided for a device that is handling significant power levels that is as small as it can be practically made and still function properly. Therefore, a device that can accomplish the described functionality is quite novel. There is a time period of as much as 20 ms of outage time while the ATS relays disconnect from one source and connect to the alternate source. This period of time means the DC power supply is dependent on the energy stored in the capacitors inside of the AC-to-DC rectifier and filter section of the power supply. This is a finite amount of storage and comprises a significant portion of the overall volume of the power supply. It is generally accepted that enough reserve power is to be kept in the storage capacitors to deliver power to the load for a minimum of 16 ms or one AC cycle at either 50 or 60 Hz. This level of energy storage has, in the past, been considered the design guideline for the minimum hold up time of major power supply manufacturers. The standard guideline given in the CBEMA (Computer Business Equipment Manufacturers Association), now ITIC guidelines, is shown in FIG. 18.

In recent years, power supply designers have been forced by financial and volumetric constraints to shave off time from that hold up period by reducing the electrical storage capacity of the PSU units. Halving the holdup time requirement cuts a very significant amount of volume from the power supply, and cuts cost. It is not uncommon for designers to now specify a maximum of 10-12 ms of outage time for a PSU unit, which requires that an ATS feeding that PSU transfer from one AC power source to another in the same time duration or less. This can become problematic for ATS units since they have mechanical components such as relays that may have difficulty actuating at the speed required. It should be noted that as relay and contact sizes and mass increase, that actuation time of the relay usually falls, since F=MA and there are practical limits to the forces that relay solenoids and springs can achieve, especially smaller ones. Faster actuation time relays and similar mechanical devices can be designed, but that almost always comes at the expense of volume since those devices require more powerful actuation mechanisms to move the electrical contacts at higher speeds. Also, speeds that are too high can result in excessive contact bounce and/or damage, which is a limiting factor. These design issues are discussed in this and the incorporated documents including, for example, the Accelerated Motion Relay case and the Z-Crush case.

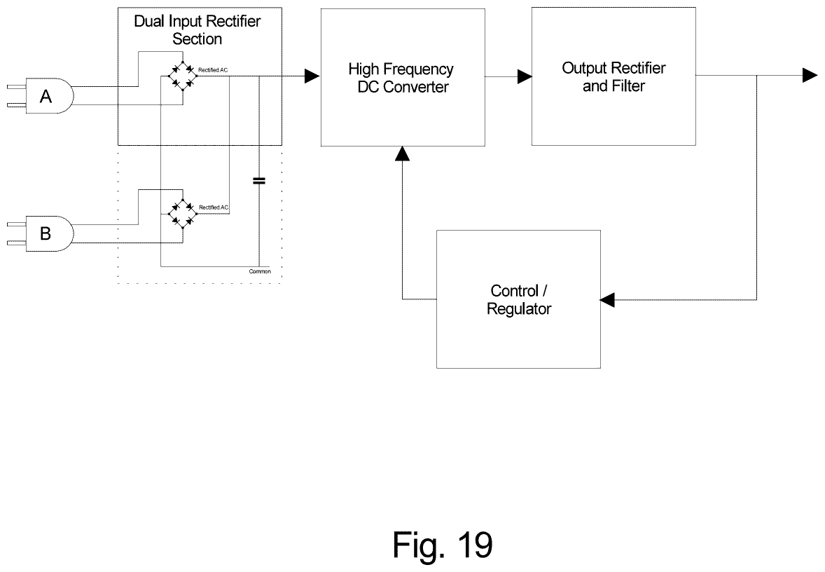

One possible invention to solve this issue, shown in FIG. 19, is to rectify from AC to DC both of the AC sources and then combine the DC outputs. This is conceptually similar to two DC power supplies delivering DC to a battery, for example.

In one possible instantiation, depicted in FIG. 19, the input rectifier section of the power supply illustrated in FIG. 17 has been duplicated. There are now two rectifier bridges that have the DC outputs of each connected together and delivering rectified AC to the filter capacitor. This is the general concept of simply using the DC output of the rectifiers and depending on the rectifiers to provide the necessary isolation. It will work if both of the AC inputs are on the same phase and in the same polarity. Whichever AC source has the higher voltage, albeit only a few millivolts, will be the source of power for the load.

However, this has a major design issue that must be considered. If the A source and the B source are not on the same phase, or the polarity of the opposing phase is flipped (180°) then there will be a higher voltage presented to the filter capacitor, and subsequently to the remaining High Frequency DC Converter. The input voltage can be as much as doubled. This would require much more robust and expensive design of the remaining sections of the High Frequency DC Converter. To understand this voltage increase, consider a three-phase AC power delivery subsystem commonly available in commercial and industrial sites.

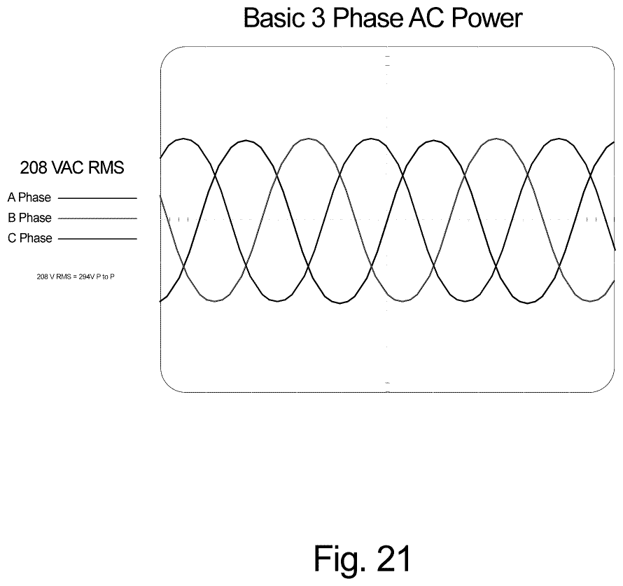

FIG. 21 is a synchogram that demonstrates the time (horizontal axis) to voltage (vertical axis) relationship of the three phases in a common three phase power delivery location. The standard nomenclature for phase A is generally represented by a black wire, and thus a black trace on our image. Phase two is represented by red, and Phase three by blue. It can be observed that the three phases are each 120° apart. Additional, in this example, we use the North American standard for typical three phase end use voltage of 208 volts RMS. That means the Peak-to-Peak voltage is around 294 volts. This will become important for this discussion later.

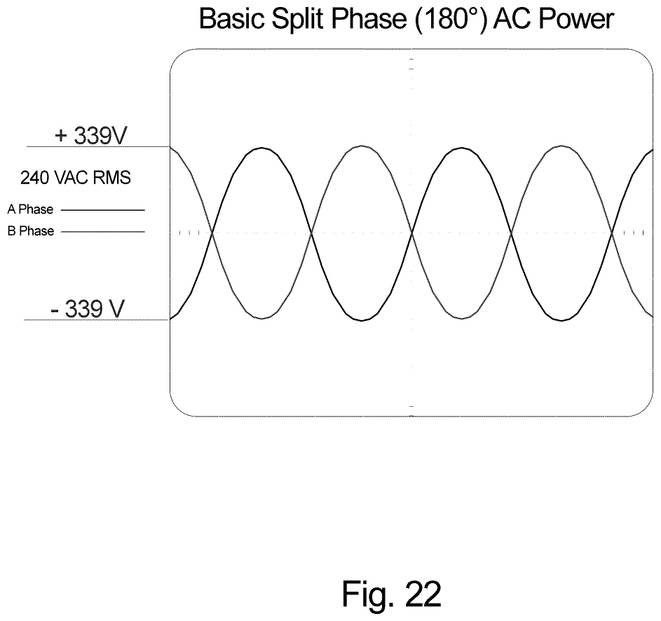

FIG. 22 is a synchogram that demonstrates what is commonly referred to as “split phase.” This is where each AC phase is 180° apart from each other. When one AC source is in the positive half of the AC cycle, the opposing source is exactly in sync but in the negative half of the AC cycle. This would be similar to the AC power delivered to most US residential locations (120 VAC to the wall outlets, and 240 VAC to the heavy loads such as the stove, the dryer or the Air Conditioner). Because there is no need for three phase power sources in the typical residential application, the simpler “split single phase” is utilized. But this configuration is also common in environments that require high availability power delivery, and in international applications where 240 VAC is the norm.

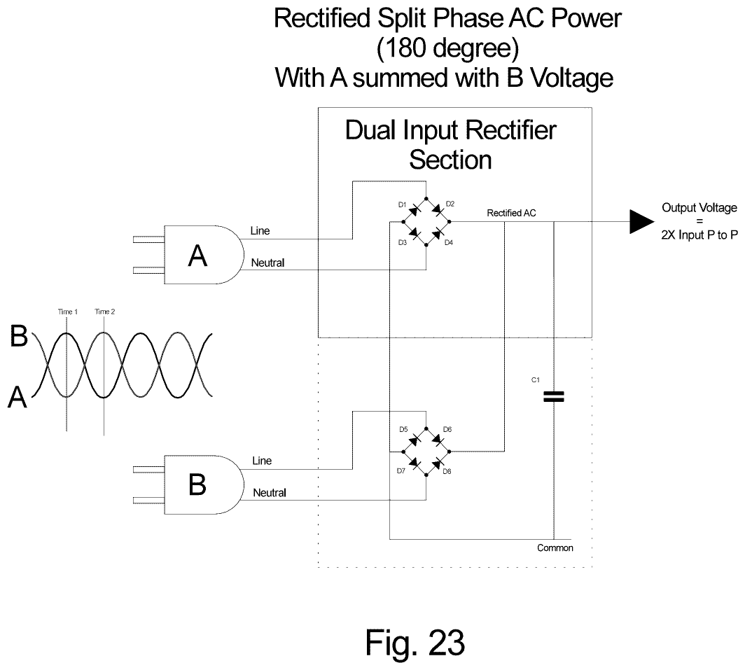

FIG. 23 demonstrates the problem with the wired together rectifiers described earlier. When A phase is at Time 1, the voltage on the Line side of that plug is positive 339 volts and current is flowing to the output and the filter capacitor via D2. Simultaneously, at Time 1, the B side voltage on the Line side is negative 339 volts and current is flowing to the load and the filter capacitor via D5. The common side of the filter capacitor is negative 339 volts and the output side of the filter capacitor is plus 339 volts, making the across the terminal voltage on the filter capacitor 678 volts!

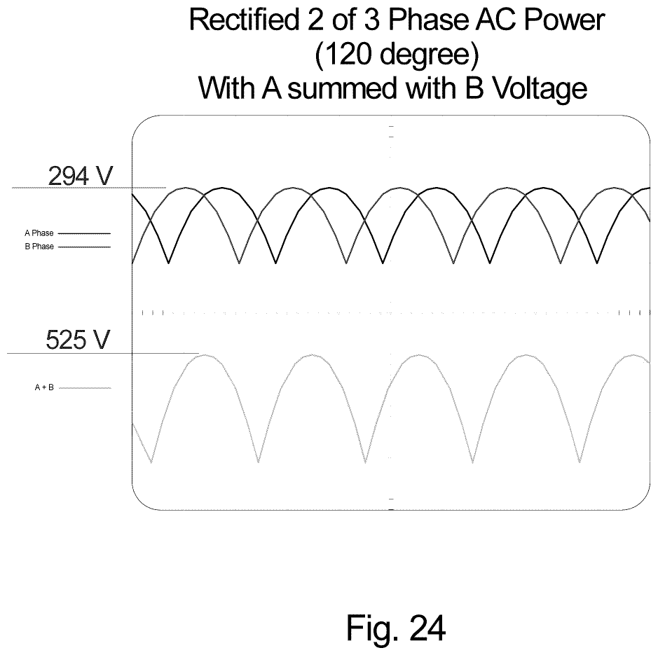

FIG. 24 demonstrates a similar voltage increasing problem but for the application bridging two phases of a three-phase system (120°). In this example, we have selected the A and B phase and are disregarding the C phase. The results are the same regardless of the phase pairing combination. But in this example, again when the A phase is past its peak but intersecting the B [phase approaching its peak, the peak of the summed AC sine wave is now at 525 volts, A side being 294V, and the B side being the same. The peak voltage applied to the filter capacitor in this case is 525V!

To solve the problem of the out of phase AC power sources delivering excessive voltage to the input of the High Frequency DC Converter section, it is desirable to not only sum the voltages of the two rectifier outputs. Summing them together is acceptable if both inputs are the same voltage and phase. If not, then one or the other must be selected but not both. This creates the question; how to select one or the other?

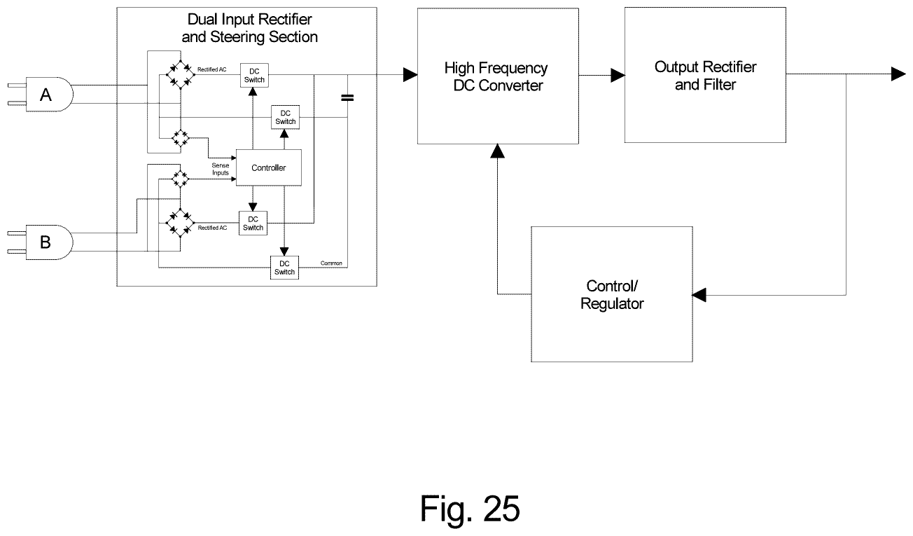

FIG. 25 shows the design of a Dual Input and Rectifier section which has added DC on/off switches in line with the DC power paths. These switches, being on the rectified side of the power path can be Insulated Gate Bipolar Transistors (IGBT), MOSFETs, SCRs or other suitable electronic components. The desired path is controlled by signaling from a controller that will turn on either the A side or the B side.

In addition, the Controller section has inputs that are representative of the AC voltage referred to as sense inputs. These are derived from independent AC to DC bridge rectifiers. It is necessary to isolate these from the DC output of the main rectifier bridges because those bridges outputs are connected to the filter capacitor and thus will only have filtered DC. The controller requires un-filtered rectified DC to decide which input has the greater magnitude at any point in time.

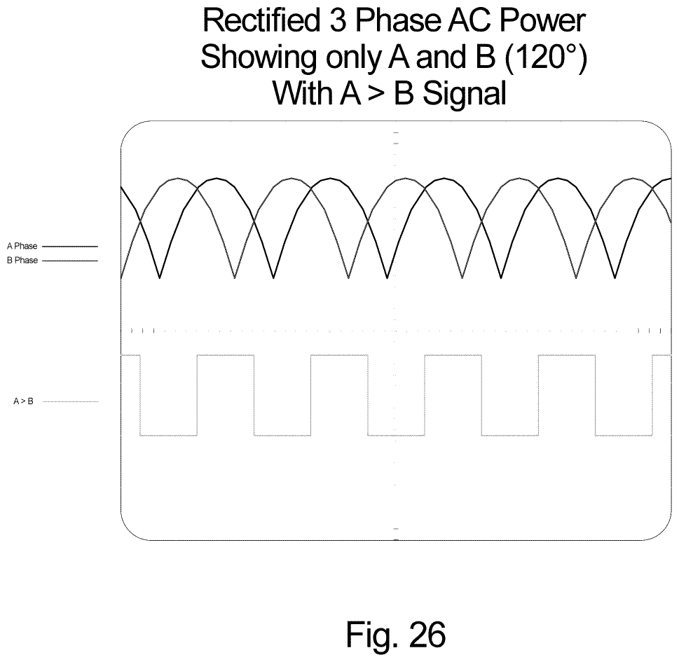

FIG. 26 is a synchogram showing the selection of phases A and B in a three-phase system (120°) for use as the two inputs to the Dual Input Power Supply. In addition, the square wave signal represents what comes out of comparing the magnitude of the A side to the B side. It can be observed that when the A side is in the rising voltage after the intersection of the two inputs with respect to magnitude, until the intersection when falling, the A side magnitude is detected and represented as a positive side of the square wave. The converse is true for the B side.

This detection mechanism allows the controlled selection of either or both of the A and B side DC power in the switches. Selection of both A and B is a unique capability that can be used to optimize the output voltage which can help to keep a connected load up and running.

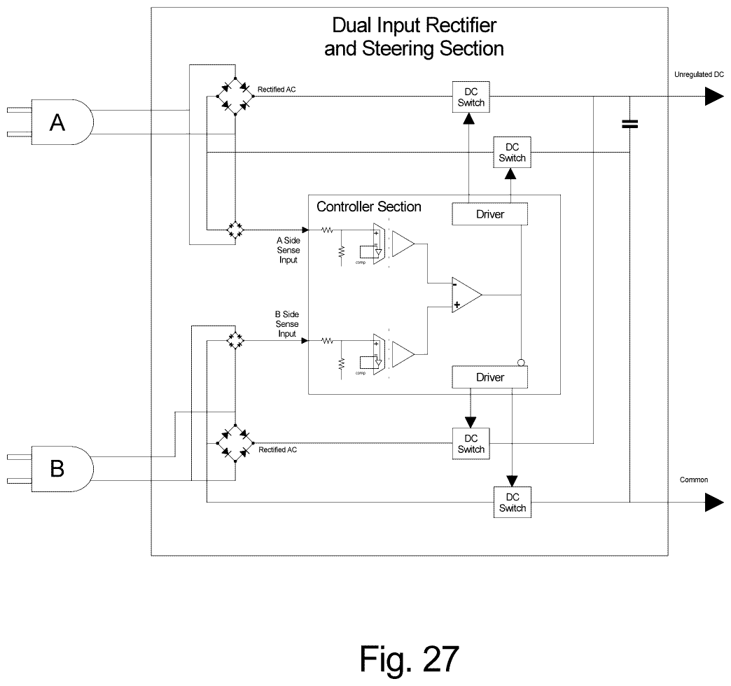

Refer to FIG. 27 which shows the block diagram of the inside of the Controller Section and observe the location of the “Sense Inputs.” These are analog buffer/isolation components. They can be transformer coupled, capacitor coupled or optically coupled or otherwise implemented. The voltage range and the isolation voltages for these devices are chosen to allow the Controller Section to function with any polarity of inputs to the Dual Input Power Supply. It is unknown if the inputs are referenced to earth ground or not, so isolation is required.

Note that the output of the two isolators is connected to a comparator that compares the analog magnitude of the two input signals. Whichever input signal is greater in magnitude will control the output of the comparator. Also notice the inputs to the DC Switch Drivers. One has an inverter on it. Thus, the drivers are always complimentary, one is always on, and the other is always off. Thus, one side, A or B, is always selected to deliver DC power to the filter capacitor and the remaining High Frequency DC Converter, but never both sides. This novel design solves the problem of the A and B sides “summing” and creating an unreasonable output voltage. Further it can be built within the constraints of the required form-factors.

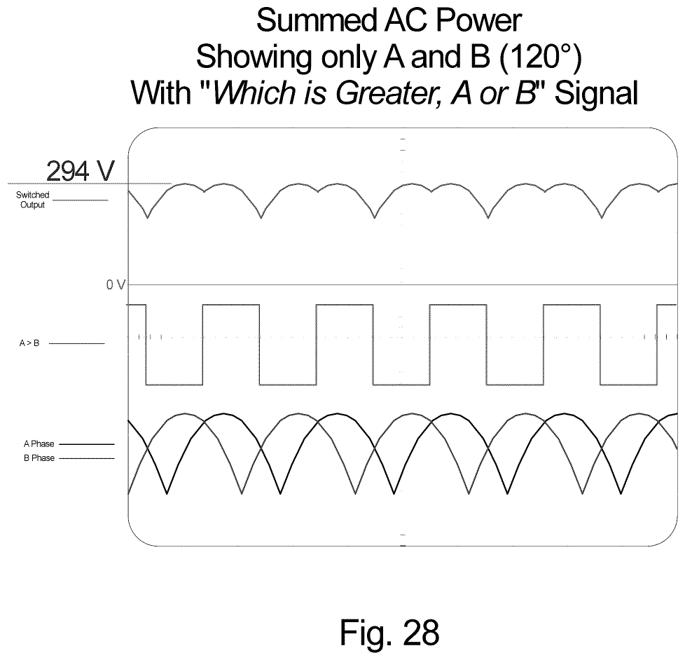

FIG. 28 shows the resulting voltage output delivered to the filter capacitor as the A and B sides are alternately connected to the Capacitor. Because there is only one path switched on at any one time, the DC level never exceeds the peak voltage of one or the other input AC sources. In this case, the 208 volts of the two pair of phases of a North American 120/208V three phase application (208×1.414).

The selection of which side to use for the power source is actually more difficult when the input power is single split phase where one AC source while increasing in voltage, the opposing AC source is exactly matching but going in the opposing direction and increasing. These AC signals are referred to as two phases again, but these phases are 180 degrees apart.

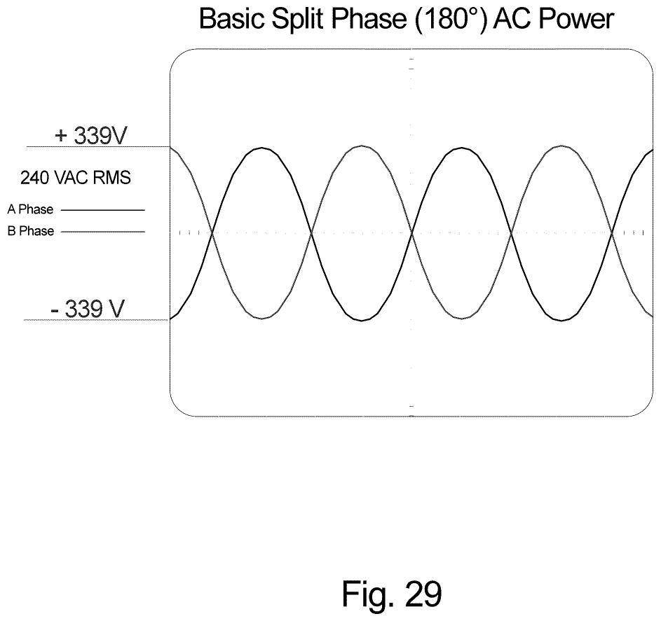

FIG. 29 shows Basic “Split Phase” which is 180° separated with respect to voltage polarity. In the case of North American power, this is not common above 120 VAC, but in international settings this is a common configuration where two 240 VAC sources are available to the Power Supply, and those two 240 VAC sources are 180° apart as shown in FIG. 29. The peak voltage on this configuration is 240× the square root of 2 (1.414), or 339V peak.

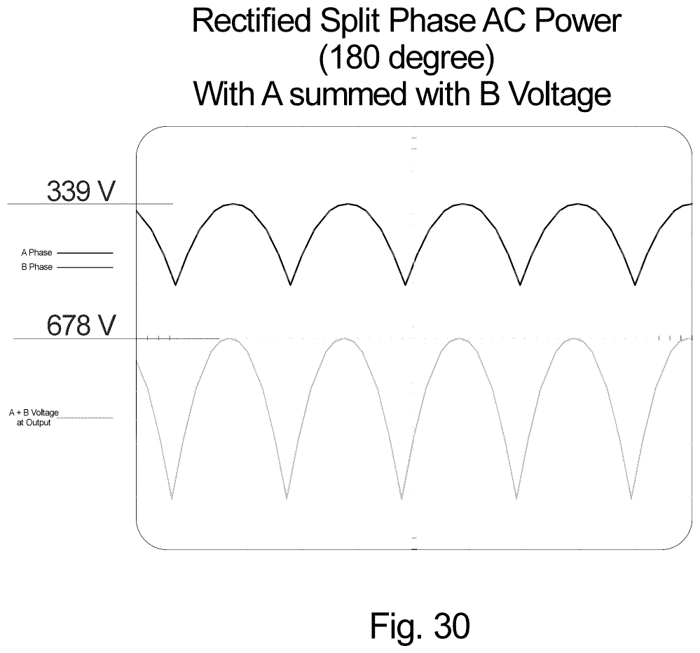

FIG. 30 shows that when rectified, the two input sources A and B are exactly matched in this case. However, the polarity is reversed with respect to the phase to phase, and thus the voltages sum if they are routed through the common connected Rectifier. That summing amounts to 678 volts peak, a difficult voltage level to work with requiring excessive margins in design and increased total volume of the assembly of the power supply. Again, as in the pair of phases of a three-phase system, the solution is to select one side or the other, preferably the one that is on. If one fails, then immediate selection of the side that is currently running is necessary.

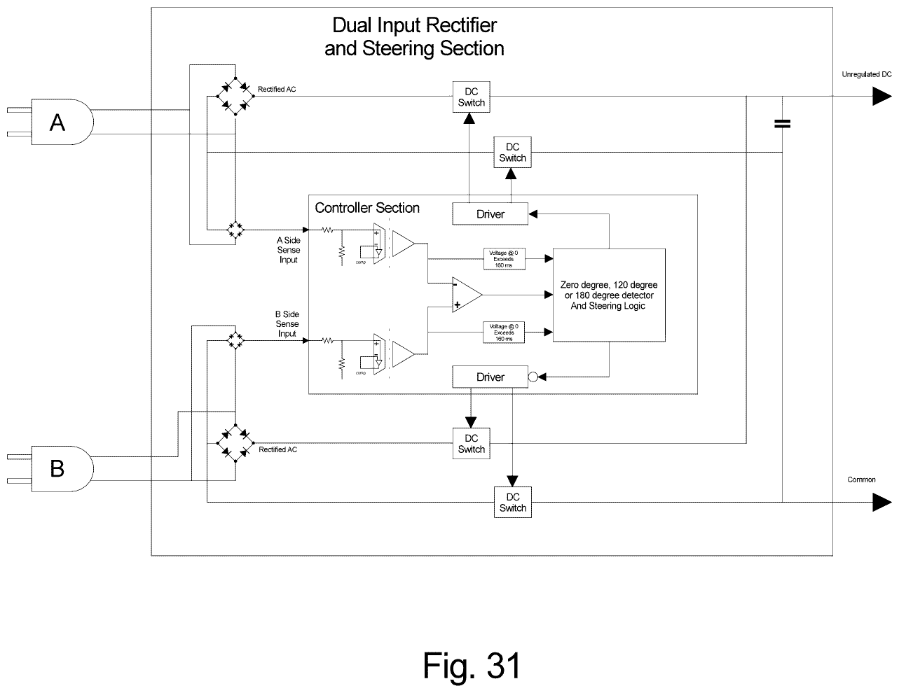

FIG. 31 shows the Controller Section which is the same as in previously mentioned sections but has an added logic layer. The outputs of the magnitude comparators for the A and B sides are routed into the additional logic section. The two signals are compared to each other and a determination is made if these are in phase or out of phase and by how much, 0°, 120°, 180°, or other value. If the phase angle is 120° the simple magnitude compare is done and the output directed to the Drivers is performed as described earlier, simply the outcome of the basic magnitude compare. If the phase angle is either 0° or 180°, then an additional function is included where an internal comparator determines if the two sides are both ON and both within 7.5% (or other value suitable for the application) of each other in magnitude. If that condition is met, then the output of the primary magnitude comparator is directed to the drivers alternately directly or inverted every 160 ms. This time is approximately 10 AC cycles in North America at 60 Hz, for example.

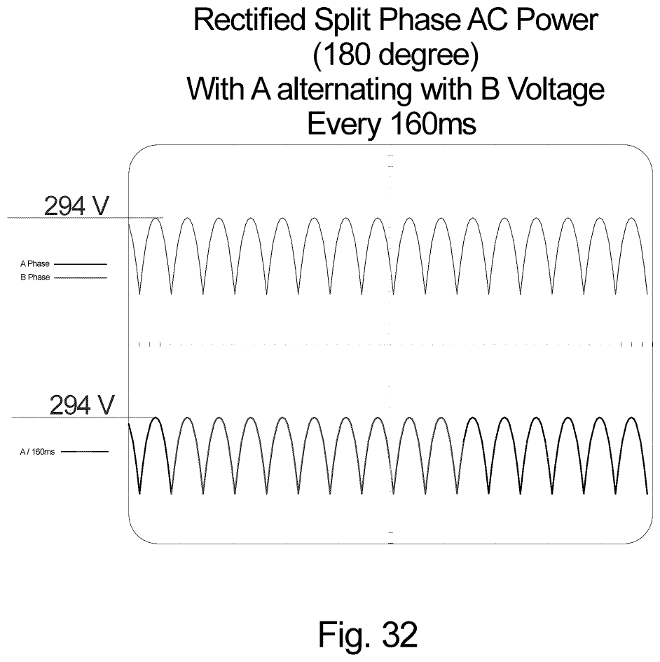

FIG. 32 shows the results of switching between the inverted versus non-inverted sources of the A side, then the B side every 160 ms. Unregulated DC power is supplied to the High Frequency DC Converter alternately from the A side then the B side at about 6 times a second. This carefully controlled switching function levels the loading of the AC Mains delivering power to the AC to DC power supply by even sharing, but in the event of an AC source failure, the selection of the greater magnitude AC source is essentially instant.

The Magnitude difference of 7.5% is selected because it is half way between the +/−10% differential used to determine if an AC source is a candidate for being considered “not adequate”, and the 5%, which is the magnitude difference that is the middle of the range of when to return to the original source when AC power is restored to a dual input ATS. The 7.5% parameter can be selected differently depending on the specifics of the end use application. The same is true for the 160 ms parameter. It can be altered to be longer or shorter, depending on the end use application.

It should also be noted, that by different configurations of the logic in the Controller Section, the Loads can be “preferred” to use one side or the other, so no load sharing is accomplished in the Dual Input Power Supply. This may result in longer service life or other desirable characteristics. The design described here allows for both load sharing and preferred side applications. Further, it may be implemented in a volume that is only approximately 125%-150% of a conventional AC to DC power supply, of equivalent power output rating, which is a significant advantage. The higher the power rating, the more volume that is needed to provide larger components and properly cool them.

AI servers and other high-power IT equipment such as blade servers require significantly increased power levels compared to traditional IT equipment power levels, as much as 5-10× or even much more in some AI processors and server roadmaps. This level of power is far more than most rack mount PDU's and other electrical distribution system elements in data centers were designed to efficiently deliver. In particular, the standard utility line voltages used in global power distribution from 100-277V are not very efficient at these power levels and demand significant increases in electrical conductor cross-section sizes. One method that has been introduced to the market is an in-rack busway in the back of the rack. This is a clumsy solution, because it fixes the depth of the IT equipment in the rack and limits the maximum depth of that equipment. It also significantly blocks cooling airflow if air cooling is used and uses significant amounts of copper and other materials. It is quite expensive. There are better ways to deliver high levels of power in an equipment rack and other environments where space is an issue. Traditional methods of in-rack power distribution evolved to allow IT equipment designers' maximum form-factor flexibility as regards equipment height, depth, location of power inlets, cooling airflow, cooling fans type and location, etc. Horizontal and vertical in-rack PDUs that use flexible power cords with appropriate wire gauges, jacketing types, endcap types and appropriate lengths, were adopted for these reasons and remain the most adaptable method for in-rack power distribution. The invention described herein preserves these important advantages but enables much higher power levels than are currently possible.

Distribution of high levels of power is well understood in industrial electrical engineering, and the most common answer is to use higher voltage to allow efficient delivery of the needed power levels with reasonably sized conductors. However, data centers and in particular data center racks are very densely packed environments, so high-voltage industrial electrical distribution components are typically too large for use in these racks. This can be overcome with inventive design. The systems and apparatus described in this, and incorporated documents, can be used to deliver much higher power levels in data center equipment racks (or any space constrained environment) using the methods described.

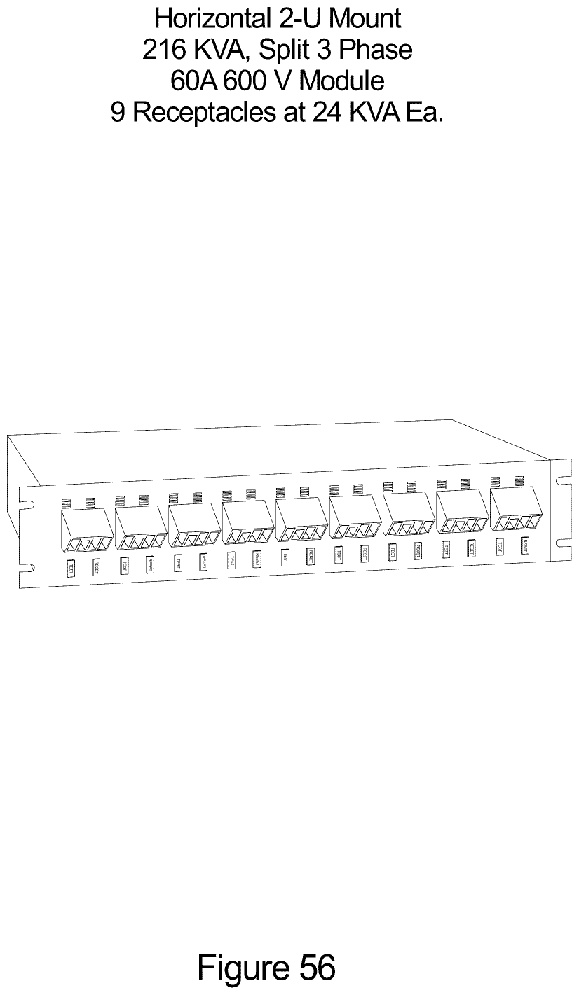

In one instantiation of the invention, an apparatus, as shown in FIG. 56, is a Power Distribution Unit, (PDU) which can be either horizontally (as shown) or vertically mounted in the equipment rack. The PDU can be fed by high voltage power, for example 600V or 1200V, which can be delivered in multiples of 20 A, 30 A, and 60 A which are common amperage moduli. Other delivery amperages and voltages are possible and may be useful, but for this instantiation we will use 60 A at 600V or 1200V to describe the invention. The other components of the power distribution system are power cords, connected to a PSU or optionally a PSU-ATS as described earlier. Each component of the system will be described below and has inventive characteristics.

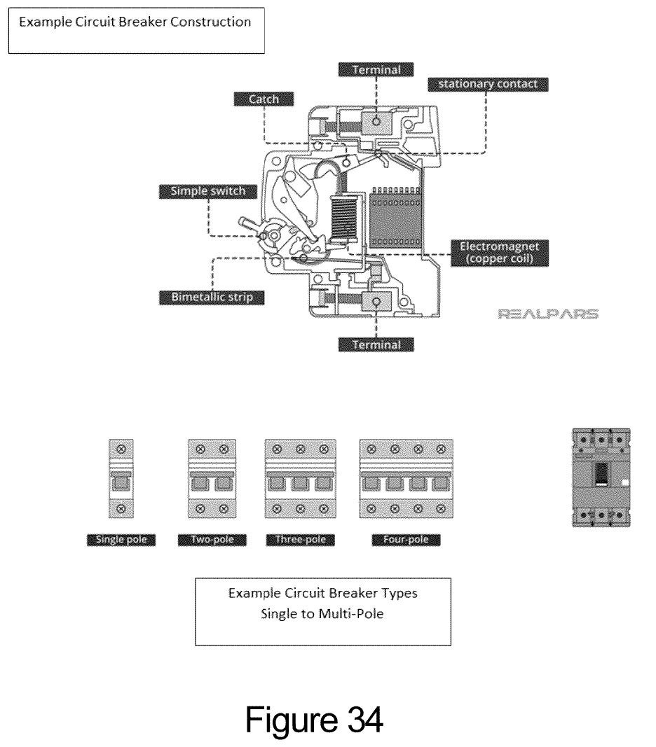

A key issue in designing high power PDUs is how to provide the space needed to contain the required electrical circuit interrupter function for one or more high powered electrical outlets. This is typically done with a circuit breaker or a fuse. For data center PDUs circuit breakers are favored because they can be opened and closed to energize or de-energize branch circuits, which is useful. They also are visually distinctive as regards being open or closed, which is very useful in complying with safety rules such as OSHA. If you disassemble and examine a typical circuit breaker you will find it has the following internal components. An example circuit breaker with components is shown in FIG. 34. Several types such as single and multi-pole circuit breakers are also shown in FIG. 34.
Contacts, connected to external lugs.
A mechanism to detect current and voltage levels.
An actuator to open the contacts when the power or voltage is out of specified limits.
A manual mechanism to open and close the contacts, although not all circuit breakers offer this feature. Some only offer the ability to close the contacts, after the circuit breaker has opened, such as “cigarette style” thermal push-button circuit breakers.

Of these components, the contacts and their armature take up the most space by far, especially for high voltage rated circuit breakers, since the contact gap must increase to provide the required isolation rating and the clearance and creepage distances also increase for the internal electrical component and paths that make up the circuit breaker.

There is a much simpler way to design a high voltage interrupter that has all of the functional features of the typical circuit breaker and uses much less space. It is to use a cordcap and an appropriate set of electrical components, one possible method is described below.

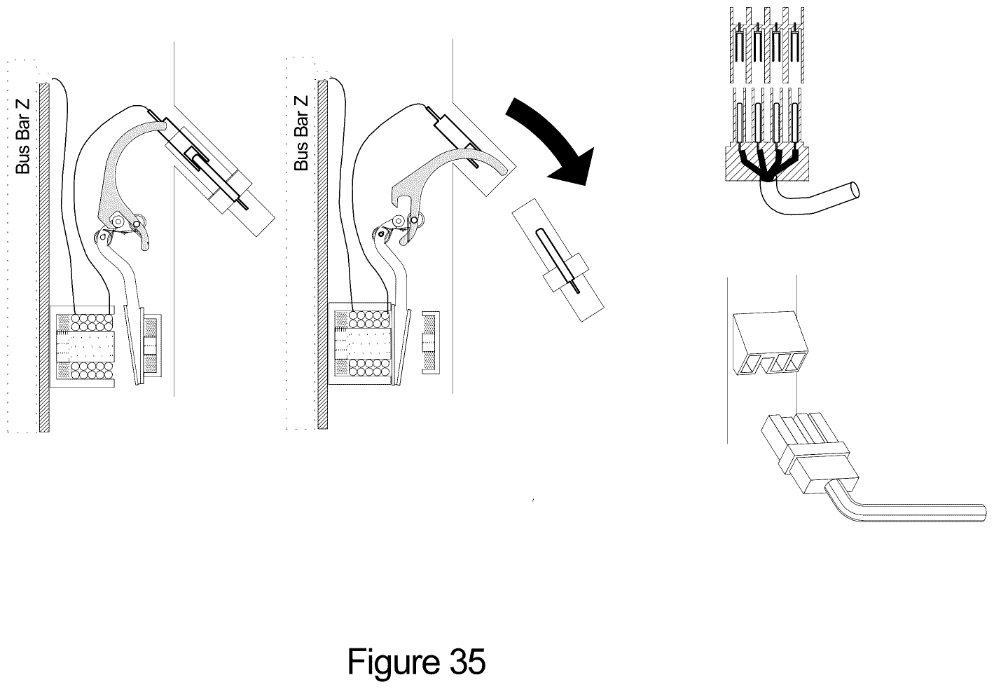

If we compare the circuit breaker described above with the cordcap+interrupter receptacle described below, we see that each needed functionality can be provided:
Contacts, which can be separated, are located in the plug and receptacle.
A mechanism to detect current and voltage levels
An actuator to open the contacts when the power or voltage is out of specified limits. This is done by one of a number of mechanisms, an example mechanism which is similar to a matchlock pistol is shown in FIG. 35. It separates the contacts of the actual plug and receptacle to the required minimum distance for the desired isolation value when activated, by causing the plug to be disconnected from the receptacle. It is reset by simply re-inserting the plug back into the receptacle. It can also incorporate an optional retention mechanism that functions to both ensure that the plug is kept in the receptacle and cannot be inadvertently disconnected when the connection is electrically closed, and the plug does not fall or otherwise move in an unintended motion when the interrupter function is triggered.
A manual mechanism to open and close the contacts, which is simply remove the cord from the receptacle. This can be done in two steps using the mechanism described above. If the intent is just to de-energize the circuit, the user can pull the plug out but not disconnect it from the retention mechanism. If the intent is to disconnect the power cord, the user can then disconnect it from the retention mechanism. One way to do this is to just pull it a bit harder the second time, disconnecting the retention mechanism.
   A key advantage of this apparatus is that the required space needed to separate the contacts is naturally provided for in the system, since there has to be space to insert and remove the plug into the receptacle. Also, it is relatively easy to provide the needed range of motion to ensure proper insolation values for the operational voltage are obtained when the interrupter mechanism is activated. Additionally, since contacts as used in circuit breakers are often designed to resist welding if arcing occurs, which is done by putting a spherical shape on each contact (think of two very large beach balls touching) and this feature increases electrical resistance somewhat due to decreased electrical conductor cross-sectional area. A properly designed linear contact, such as are used many plugs and receptacles (for example “C” shaped or “box” contacts) offer superior electrical conduction and lower resistive losses and heating due to increased effective electrical cross-sectional area. This is an efficiency advantage, which is desirable at the high energy levels that we are talking about delivering.

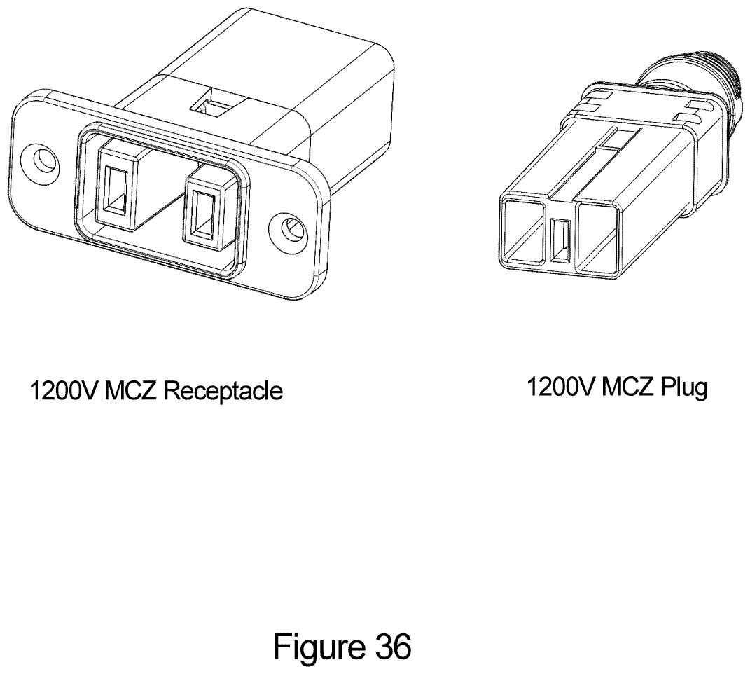

Another key component of the apparatus are the types of power cords and cordcaps that can be used with this system. There are many possible options, several will be described herein, but others are possible. In the first option, standard 600V electrical components are used. This is very commonly available for the necessary electrical distribution devices, such as wiring, power distribution panels, circuit breakers, etc., and is not expensive, because of the large production volumes. These 600V components can be used with a plus-minus voltage A/C delivery mechanism, where each conductor in the branch circuit that the power cord is part of is never driven above 600V but the difference between the hot and neutral is 1200V. This is done in the same way that 240V split-phase electrical distribution is done, via two A/C waveforms that are 180 degrees out of phase. This can be done using commonly available transformers with appropriate taps. At a nominal current of 20 A, this power cord can deliver up to 2.4 kVA, a very high-power level. This scales to almost a megawatt per rack with only 40 power cords! The power cord needed to do this is relatively small diameter and flexible. One possible cordcap can be very similar to the zMC19, which is previously described in the incorporated documents. One modified example that has the needed characteristics is shown in FIG. 36. It could be designed to be used with the receptacle+interrupter apparatus or be designed to be used as a standard cordcap and receptacle, with the interrupter function being done elsewhere in the branch circuit. This cordcap could be used in a 600V or 1200V single-phase distribution system.

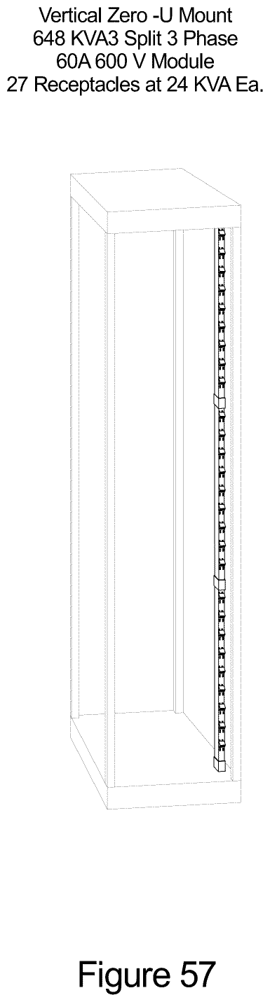

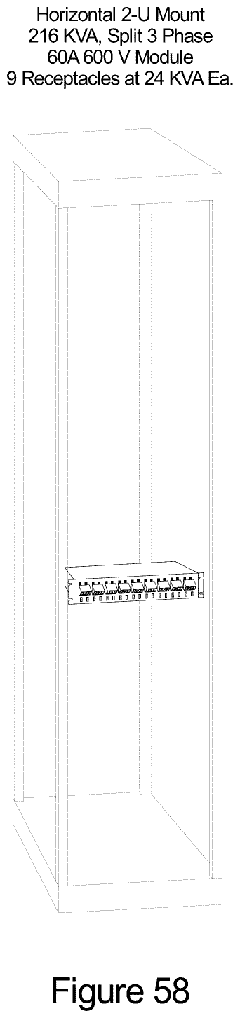

An example set of PDUs, (one vertical, one horizontal) that incorporate the inventions described herein are shown in FIGS. 57 and 58. This shows how very high-power distribution levels can be achieved in similar volumes and shapes compared to existing vertical and horizontal PDUs. Other instantiations are possible to meet a variety of requirements, but a key point is the power level for the kind of PDU (vertical or horizontal) and the volume of rack space used. As noted in the incorporated documents, rack volume matters, because data center space is costly and, at increased power and cooling levels, getting much more expensive! The inventions described herein can be incorporated with other Zonit inventions to provide maximized computer density in data center IT equipment racks and other environments. Lastly, it should be noted that the potential cost advantage that this invention has over other existing or proposed high power distribution methods for equipment racks is huge. The potential difference in cost is many multiples.

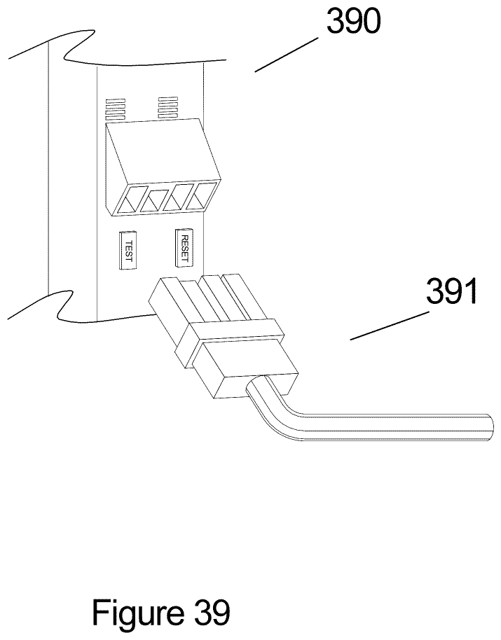

In one preferred instantiation of the invention, an apparatus, as shown in FIG. 39, has the following components. It can also operate with either 600V or 1200V power sources as described earlier. Three phase utility power is delivered to the site at preferred utility voltages for the region and stepped down to standard 600 Volt AC three phase with split single phase voltage outputs. Thus, distribution in this example can be made at 600 VAC which is still in the “Low Voltage” category that is compatible with COTS (Commercial Off The Shelf) electrical components, especially the branch wiring cable and mains. For example, the common branch wiring material referred to as type THHN (Thermoplastic High Heat-Resistant Nylon-coated) cable, is most commonly available as 600 VAC rated. This extremely high volume production material comprises a major element of the cost of deploying electrical systems, and the high volume and industry acceptance assures minimized costs associated with deployment.

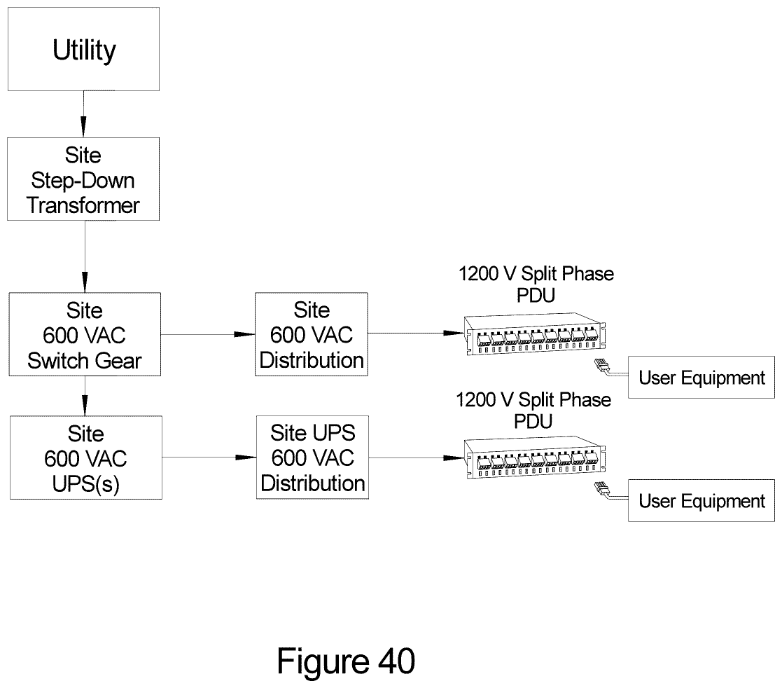

FIG. 40 represents the typical delivery of utility power to the end use (User) equipment. This equipment utilizes either existing power supply technology for 600 VAC mains in a split single-phase configuration, or 1200 VAC single phase power supply technology.

Utility power is stepped down to “split phase 1200 VAC” branches, typically but not necessarily required three phase sets of those split single phase branches. It is distributed with traditional 600 VAC limited wiring and distribution means to the object of this invention, the 1200 VAC PDU units. Utilizing embedded circuit protection (circuit breakers) and the optimized plug and receptacles, these Power Distribution Units (PDUs) efficiently distribute the power to the equipment loads with the minimum total volume for the amount of power delivered, e.g., highest power density in the industry.

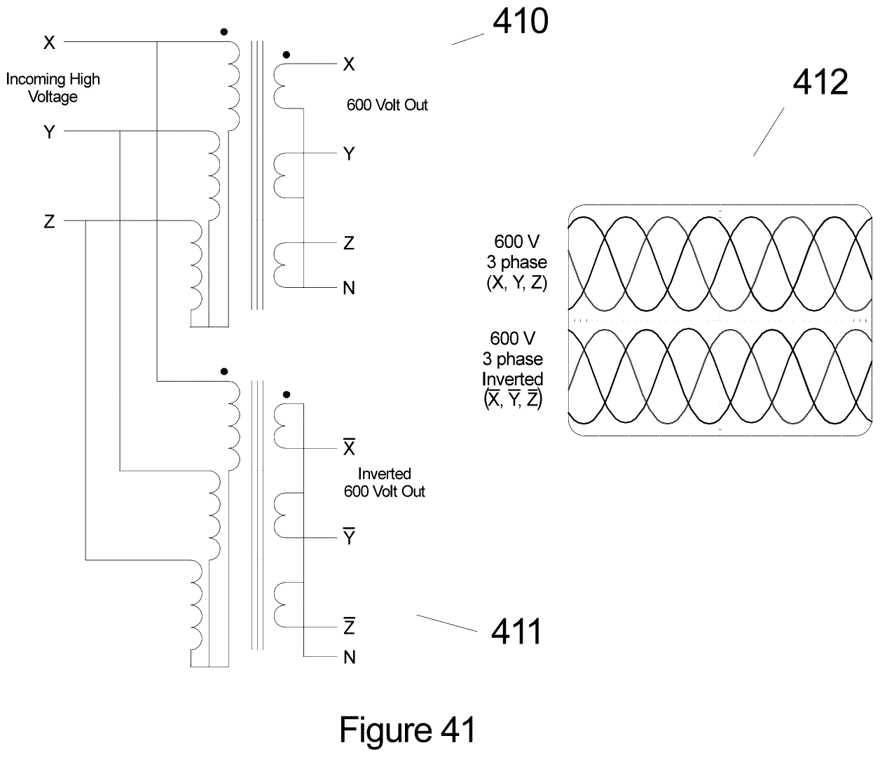

FIG. 41 shows how incoming AC power is typically delivered via a step-down transformer (410). This transformer takes the incoming delta configured (no Neutral) utility power at the regional voltage, often these range from 4 kV to 35 kV, and step it down to the 600 VAC three phase Wye configured (includes a Neutral). A second transformer (411) is shown that duplicates the first, with the exception that the phase relationship of the three outputs are inverted from the upper transformer.

The synchogram (412) shown shows the relationships of each of the three phases (shown as black is phase X, red is phase Y, and blue is phase Z) with regards to time. It can be observed that these three phases are each 120 degrees from each of the others. It should also be observed that for a given phase, for example X, that the top transformer and the bottom transformers are 180 degrees out of phase with each other. Thus, for any one individual phase, X, Y or Z, there is a counterpart that is 180 degrees opposite. For any one phase, the sum of the voltages for a phase and its counterpart is 1200. Thus, three individual 1200 VAC branches are available in this configuration, each 120 degrees from one another.

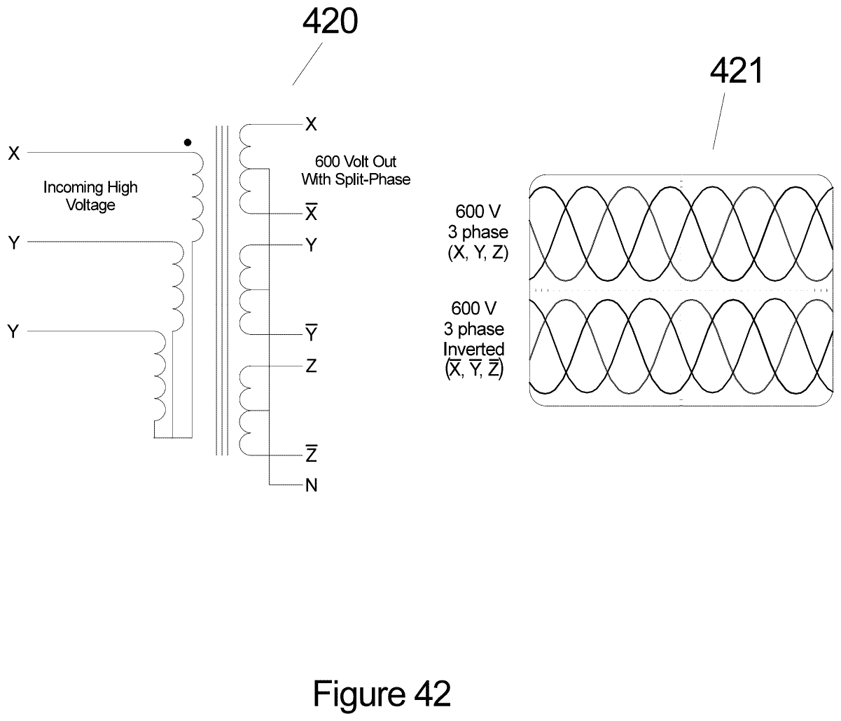

FIG. 42 shows the effect of combining the two transformers described in FIG. 41 into one transformer (420). This is wired and configured essentially the same as either of the transformers in FIG. 41, except the output windings are merged to allow a center tap on each of the phases, and the voltage of each output tap is doubled to 1200 VAC. However, since there is a center tap, that center tap can become the Neutral in the distribution system and each of the legs attached to that Neutral become a 600 Volt and a 180 degree opposing 600 Volt branch set, e.g., “Split Phase.”

Again, the synchogram (421) shows, for example, Phase Y (red) in X being 180 degrees out of phase with the opposite side of the split phase, Not-Y. The result is that voltage from Y to Not-Y is 1200 VAC, but because all of this is relative to the Neutral, and the Earth Ground, 600 VAC rated wiring can be utilized.

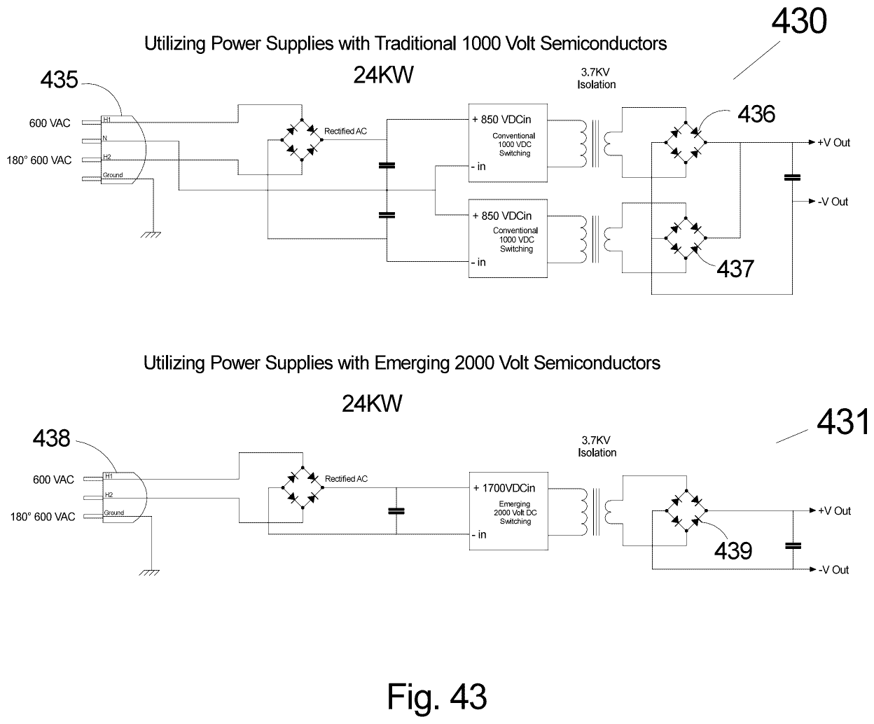

FIG. 43 shows the end use power supply arrangement that takes advantage of this invention. Reference numeral (430) shows the configuration of a possible PSU that utilizes this higher voltage AC power delivery invention. This power supply utilizes existing low cost off of the shelf components to construct a power supply configuration with 600 VAC inputs. The four conductor connector (435) is part of this invention, it is a compact 1200 VAC Split phase 15 or 20 Amp connector utilizing characteristics of the Zonit zmC19 style connector, as described in the incorporated documents including, for example, the Monitoring Module case, with additional length for safety and isolation requirements, and an additional conductor for delivering the “Split Phase” so the connector can deliver two 600 VAC circuits. These two AC sources are 180 degrees out of phase with each other with a common Neutral. The Split phase is delivered to a traditional pair of power supplies designed to operate with a minimum of 600 VAC with the output rectifier of power supply 1 (436) wired in series with the output rectifier of power supply 2 (437) resulting in 1200 VAC delivery to the end use equipment.

Technology is changing fast, and low-cost components with elevated operating voltages in the region of 200 Volts and better are soon to be available. When that occurs, the two power supplies mentioned in (430) can be combined into one single power supply (431). In that case, an alternate, more compact connector (438) will supply AC power (part of this invention) to the end use power supply. This power supply takes the rectified 1200 volts directly and convert it to DC via the single bridge rectifier (431).

Both of these configurations occupy about the same total volume as two conventional PSUs mentioned earlier, but with as much as 24,000 Volt-Amps of capacity.

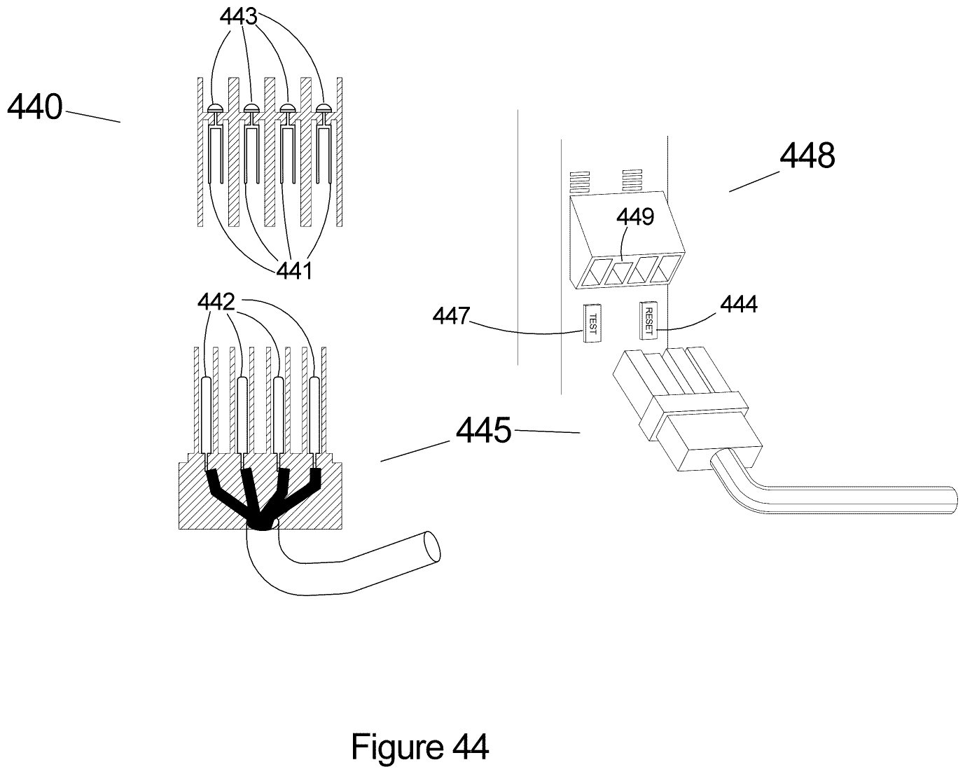

FIG. 44 represents an instantiation of this invention with a connector (448) that can have an integrated safety disconnect system (440) that utilizes four conductors (441) Ground, Phase (N), Neutral, and Phase (Not-N), where the phase is 180 degrees different from the phase between the ground and the Neutral. The power cord connector plug (445) shown is comprised of individual male interconnect pins (442), either blade or circular, a housing, a cable holder and/or strain relief, (for example the zLock strain relief mechanism as described in the incorporated documents including, for example, the Programmable Release case), and commonly available 600 VAC rated power cordage to connect to the end use equipment. The commonly available 600 Volt rated cable is adequate for delivering the 1200 VAC split phase power to the end use equipment, and because it is produced in large volumes, the cost is minimized. The power receptacle connector (450) shown in this example can integrate a safety disconnect (current interrupter) function.

The receptacle (450) can be used in both IT equipment or in horizontal or vertical Power Distribution Units. The receptacle (450) can be used in both electrical equipment or with horizontal or vertical Power Distribution Units (PDU). Examples of this are shown in FIGS. 57 and 58.

The receptacle (450) has four sets of receiving contacts, either blade or circular, each electrical contact includes an integrated Tungsten-Silver Contact (443) (or similar appropriate material typically used for power handling contacts) on each connector. An integrated electrical insulation barrier is included between each of the contacts that provides the required creepage distance requirements for safe insulation of the 600 VAC contacts.

It should be noted that either a Ground or a Neutral will be configured between any two elevated voltage contacts to allow meeting the creepage requirements for 600 VAC. The integrated tungsten silver contact (443) will be an integral part of the circuit protection disconnect means (circuit breaker) for this individual connector.

Integrating the circuit breaker in the receptacle will allow for a higher current distribution to multiple individual receptacles, much the same as any common circuit breaker cabinet would, except this Circuit Breaker will be located directly at the receptacle physical location for the purpose of minimizing the volume required to construct the Power Distribution Unit (PDU).

This circuit breaker assembly can also include a reset button (444) to allow resetting a circuit breaker that has been overloaded, or “tripped.” An additional test button (447) can be provided to test the circuit breaker to allow actively testing its functionality, or to use to shut off the individual branch circuit at that receptacle.

It should also be noted that one of the insulated conductor housings (449) is significantly different from the other three. In this case, one is smaller, but it could be shaped differently or have a key. The purpose is to guarantee that the connector can be inserted in only one orientation.

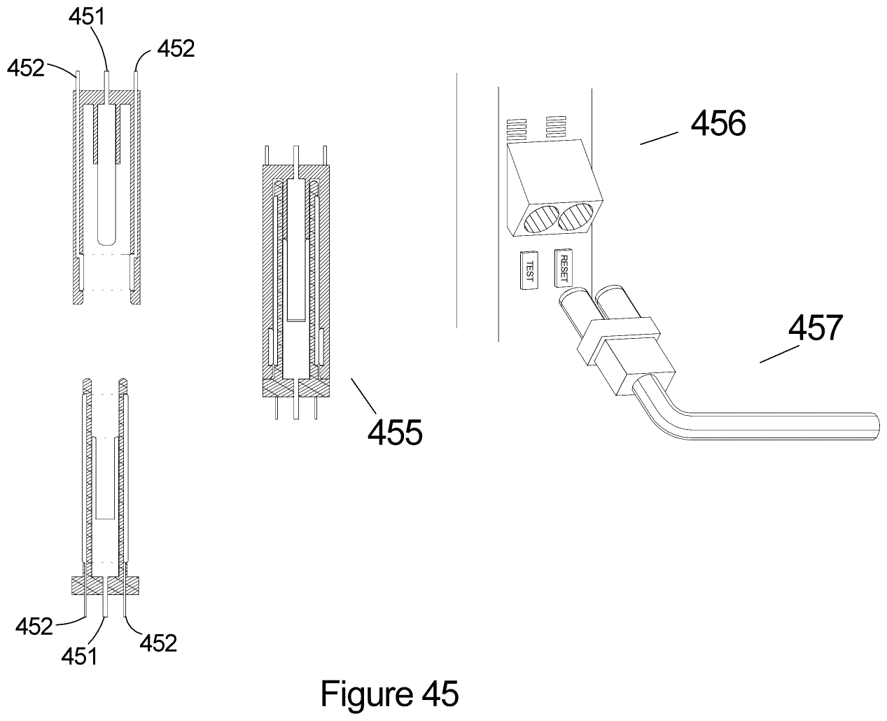

FIG. 45 shows an alternate configuration of the connector method described earlier in FIG. 44. This circular connector is co-axial in configuration and each prong actually has two conductors. One is the elevated voltage conductor (HOT conductor) (451) and the other is either Ground or Neutral (452), one on the inside of the insulation tube and the other on the outside thus maintaining the minimum of 600 volts creepage distance separation for safety. It should also be noted that the HOT conductors (451) are recessed in the insulation material in such a manner as to improve safety from allowing the conductors to have exposure to either inanimate or animate conductors external to the intended conductor path.

The mated pair of conductors (455) show how the coaxial mating occurs, allowing the HOT conductor (451) to be totally encased in either the Earth (ground) or Neutral referenced conductor (452), further advancing the safety of the connection.

The main advantage of the coaxial power connectors is the reduction in overall size. This connector is about a third less volume than the aforementioned four pin connector (440).

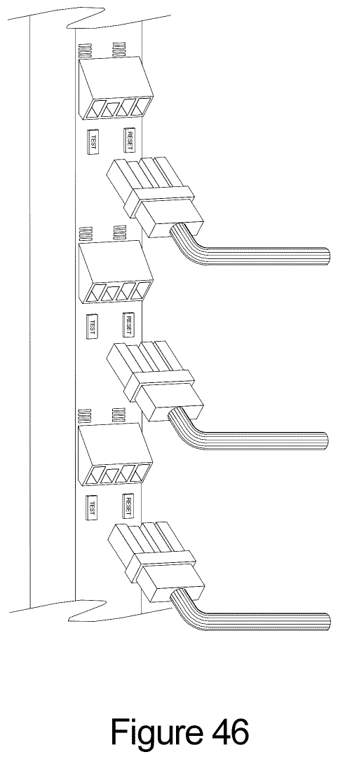

FIG. 46 shows a three phase sub-group of the high voltage connectors on a single section of a Power Distribution Unit (PDU). Each connector represents a split phase power tap of one of the primary three phase sources. For example the top connector might be X and Not-X, the middle connector could be Y and Not-Y, and the bottom connector would be Z and Not-Z. Each of these receptacles can be current limited to the required amperage via an integrated Circuit Breaker, which in this example would be rated to 20 Amps. A four receptacle group with 15 A ratings is also feasible.

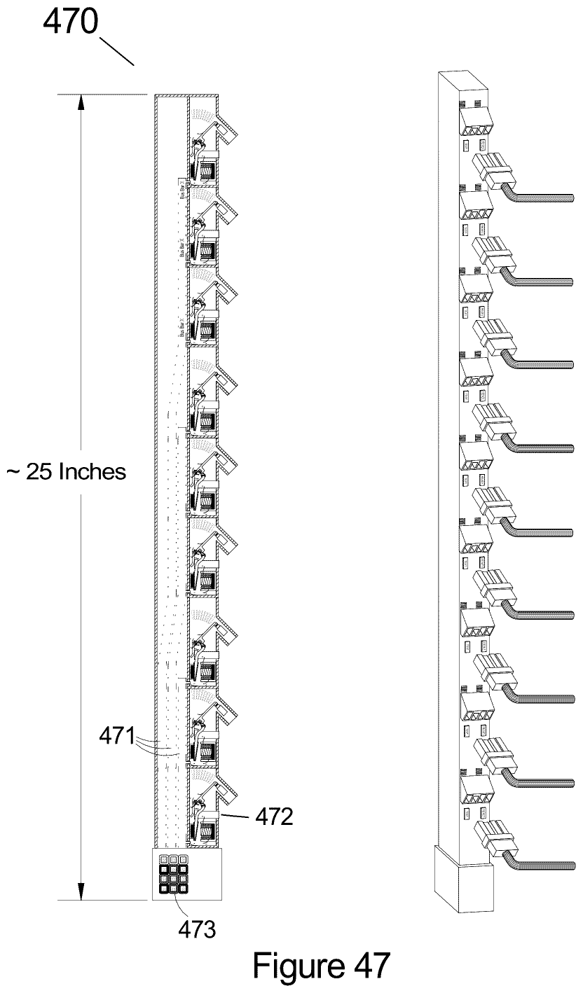

FIG. 47 represents a vertical PDU with nine individual circuits, with three 60 A feeds, each powering a group of three outlet receptacles as described above. This PDU, which includes an individual Circuit Breaker for each outlet with a 20 Amp 1200 VAC receptacle is capable of delivering 216 KVA as shown in FIG. 47. The short length (˜25″) of this PDU means that multiple PDU sections (which can be electrically connected or separated as needed) could be combined into one mechanical chassis of an appropriate size to allow convenient rack mounting and deliver even greater power densities. This concept and its variations are detailed in the incorporated documents including, for example, the Management Module case.

It should be noted that because the busbar (471) distribution to the circuit breakers is typically 60 Amps, the circuit breakers could easily be rated for 15 Amps if it were useful to have it so. In that case, the 60 Amp busbar would break out to four circuit breakers per phase, or twelve total receptacles for this one three phase module. This variant of the Invention is not the preferred instantiation but is a useful alternative.

The cross section of the side view (470) shows each Circuit Breaker and the busbars (471) that feed the circuit breakers (472). The bus-bars in this case are 60 Amp and have cross sections that are adequate for delivering the 60 Amps will acceptable levels of loss and heating when operated at full capacity. Minimal heating is desired, thus the cross sections are optimized. The insulation of the bus-bar that separates the conductors is individually configured for each conductor and is rated to a minimum of 600 VAC, including the Ground and the Neutral conductors. The three by four array shown (473) is an example of a desired layout of the conductors to maximize the efficiency of distribution and make manufacturing of the three phase variant of this vertical plugstrip simplified.

The three sets of busbars are offset towards the circuit breakers as they rise through the plug strip in a manner that allows each of the circuit breaker sets that tap an individual phase to be constructed the same as all of the other circuit breakers. In other words, the buss-bar conductors are bent to facilitate connection to the circuit breakers as needed.

It should be observed that the busbars can originate from the top of the plug strip as easily as they can originate from the bottom. This allows the alternate method of delivering power to the plug strip from overhead instead of from underneath. The overhead delivery system will likely be the preferred instantiation due to the convenience of overhead wire-ways for managing large amounts of heavy power cabling. Both delivery methodologies have advantages and disadvantages, thus the design easily adapts to either configuration.

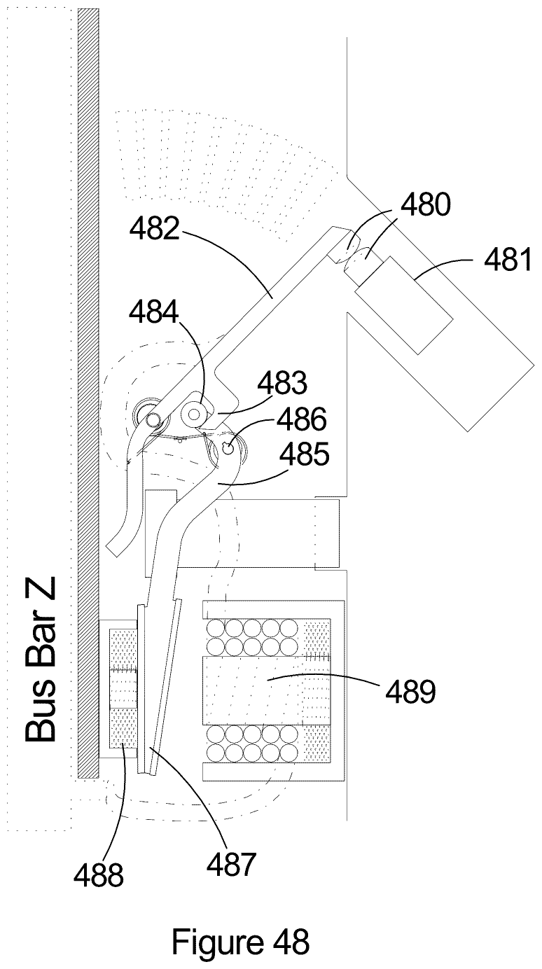

FIG. 48 is a cross-sectional side view of the general mechanical configuration of one possible design of a circuit breaker that can integrate with the receptacle (450). Two key components of the circuit breaker are the contacts (480) that are typically made from a Tungsten Silver alloy and the electrical receptacle socket conductor (481) that interfaces with a mating plug that connects to the end user equipment. The circuit breaker Moving Contact Arm, (482) is the moving part of the electrical disconnect means for the circuit breaker. It has the movable contact and also incorporates the Sear that allows the release of the connection of the contacts (700) when initiated by the release Pawl Roller Wheel (704). When the Pawl Lever (485) rotates about the axle coupling (486), the release Pawl Roller Wheel (484) traverses the surface of the Sear (483) with minimal force due to the nearly right angle displacement of the relationship of the Sear (483) and the axis of rotation of the Pawl Lever (485). This is a critical element of this design as it makes the actuation forces of the release mechanism highly repeatable and predictable, regardless of the external influences to the mechanism. This is the “triggering” mechanism that releases the connection of the current carrying contacts. To make the assembly highly reliable and accurate, this roller wheel on a precise angle ramp allows the desired repeatability by minimizing friction and having a predictable force for actuation defined by the relationship of the angle of the ramp surface of the Sear (483) and the rotational path of the Pawl Roller Wheel (484). In this instantiation the roller wheel of the Pawl is brass or bronze while the axle of said roller wheel is hard steel. This is a simple to manufacture combination that has a very high level of reliability and can operate for very high actuation counts, both are desirable characteristics for this application.

The actuation of the Pawl Lever (485) is accomplished by rotating it about the pivot axle coupling (486), in this example in a counterclockwise direction. The force to rotate the Pawl Lever (485) is provided by the electromagnetic assembly consisting of the Magnetic Armature (487), the Hold Coil (488) and the Current Sense and Actuation Coil (489).

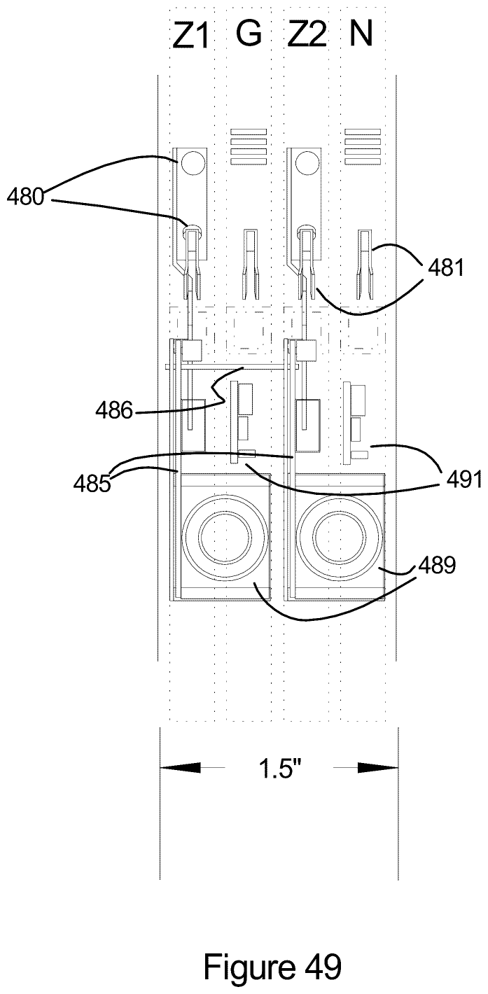

FIG. 49 is the front cross section view of a circuit breaker assembly as observed from the electrical connector side. This view is a phantom cross section intended to help identify the major components of the circuit breaker assembly that includes two individual circuit breaker assemblies, one for each of the elevated voltage connections (Hot) for a given receptacle, along with the Ground and the Neutral paths, and how these four conductors are organized with respect to each other.

The main current paths are designated in this case as “Z1”, the 600 Volt elevated phase associated with this circuit breaker, G the Ground, Z2, the 600 Volt 180 degree offset elevated phase associated with this circuit breaker, and N, Neutral.

These are organized in this fashion to minimize the voltage relationship between the elevated voltage (hot) conductors by having a ground or near ground referenced set of conductors in between each of the hot conductors. This arrangement will improve the long term reliability by minimizing the arc potential between elevated voltage components. In this case, a maximum of 600 VAC exists between any two current capable conductor assemblies as opposed to 1200 volts if two hot conductors were to be placed adjacent to one another.

In addition, the Pivot Axel Coupling (486), about which the Pawl Levers (485) rotate when actuated is shown linking the two Pawl Levers (485) of the two circuit breakers together in such a manner as to result in both circuit breakers actuating if either actuator coils (489) are energized. An overload on either or both Hot conductors results in disconnection of both current conduction paths. This Pivot Axle Coupling (486) is comprised of a non-conductive material such as fiberglass or suitable plastic. It is keyed is some fashion at each end to mechanically bind the Pivot Axle Coupling (486) to the associated Pawl Lever (485) on each end of the Pivot Axle Coupling (486). Shown in this example is a simple key, but it also could be a square or a spline of some appropriate style. In addition, a 1.5″ dimension line has been added to lend some perspective to the overall minimum estimated width of the full 1200 VAC connector assembly from the front view perspective. The total connector size is only slightly larger than a traditional 250 VAC IEC type C19/20 connector combination when they are joined. The Electronic control circuit board (491) is shown in its approximate location.

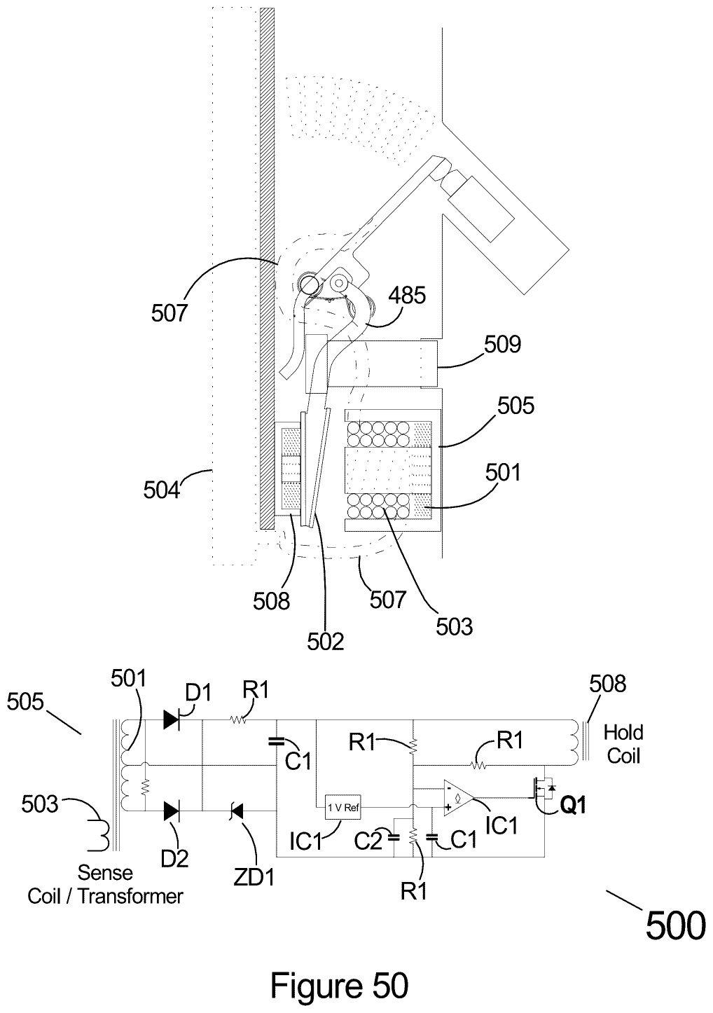

FIG. 50 includes the schematic (500) of the electrical components associated with the detection of the amount of current in the circuit breaker path, and the actuation of the disconnect mechanism. This diagram also relates the electronic components of the circuit board to the physical components of the actuation mechanism that operates the contact disconnection Pawl.

The basic circuit operates by applying a magnetic force to an Armature (502) with a Main Magnetic Actuator Coil (503) when the current threshold is reached that exceeds the design rating for the Circuit Breaker. When a magnetic field is present in the Main Magnetic Actuator Coil (503) due to current passing through the circuit breaker via connecting wires (507), and that current is not greater than the design trip threshold for the Circuit Breaker, then the only result is current is induced into the Transformer Coil (501). The turn ratio between the Sense Coil (503) and the Transformer Coil (508) is many-fold; 40 to 1, up to 100 to 1, are possible examples. Thus, the Sense Coil/Transformer assembly (505) becomes a current transformer which supplies power to the Current Detect and Actuator Amplifier circuit (500).

The very presence of even a small current in the circuit breaker results in sufficient power being delivered to the electronic circuits to operate them. Current in sense coil (503) is induced through the iron core of the sense coil/transformer assembly (505) and induces current into the Transformer windings (501). Because the current and voltages exchange in a transformer, the stepped down current becomes stepped up voltage. The design characteristics of this assembly results in 3 or 4 volts appearing at the inputs to the diodes (D1, D2) when only about 2 Amps are present in the circuit breaker path. This means that the electronic circuit starts operating at a much lower current threshold than is necessary to require disconnection of the main current path.

The Transformer Coil (508) output is a center tap coil allowing only two diodes to be required to deliver full wave rectified power to the storage capacitor (C1). Utilizing Schottky Barrier type diodes, the voltage loss through the diodes is minimized. Stored energy in the Capacitor (C1) is available for use in the detector circuit and to power the de-energizing circuit, as well as having excess power to operate the Hold Coil (508). This is a main feature of this Invention. The current going through the circuit breaker is utilized to supply a holding current in a coil that grabs and holds the Actuation Armature (502) and will not let it move until the electronic detect circuit removes the current from the Hold Coil (508) by turning OFF the Semiconductor Switch Q1. When the desired trip current is achieved, the Sense voltage applied to the electronic Comparator at IC1 exceeds the reference voltage from IC1 and the comparator output shuts off the input to the Hold Coil (508) by shutting off the Semiconductor Switch Q1.

At this time, the field strength of the Main Magnetic Actuator Coil (503) is drawing on the Armature (502) with more than adequate force to overcome the friction and mechanical resistances in the mechanism, and the Armature (502) is strongly attracted to the Main Magnetic Actuator Coil (503) causing the Armature (503) to start to rotate counterclockwise (from this viewpoint). This is the point where the circuit breaker is about to disconnect the load. The advantage of this circuit is that it can initiate the disconnection at a very specific and controlled point, regardless of the temperature, and the mechanical condition or characteristics of the components. The trip point of the circuit breaker will be very repeatable regardless of environmental conditions, age of the components, wear or other factors that could affect the long-term accuracy or reliability. In addition, this design also allows for a means for disconnection at very high currents such as in response to a short circuit. Because the current delivered to the Hold Coil (508) is predictable, there is a point when the magnetic field induced in the Main Magnetic Actuator Coil (503) is drawing on the Armature (502) with enough force to overcome the magnetic hold of the Hold Coil (508), and the Pawl Lever (485) is going to start to rotate regardless of the condition of the Hold Coil (508). In addition, this design is fail-safe in the regard that if the electronic components fail for any reason, the electro-mechanical aspects of the design still persist and the circuit breaker will still function, but at a lower total current threshold than if the electronic circuits were operational. ZD1 ensures that the electronic circuits are not exposed to excessive voltages in the event of very high inrush currents that the circuit breaker assembly might be exposed to.

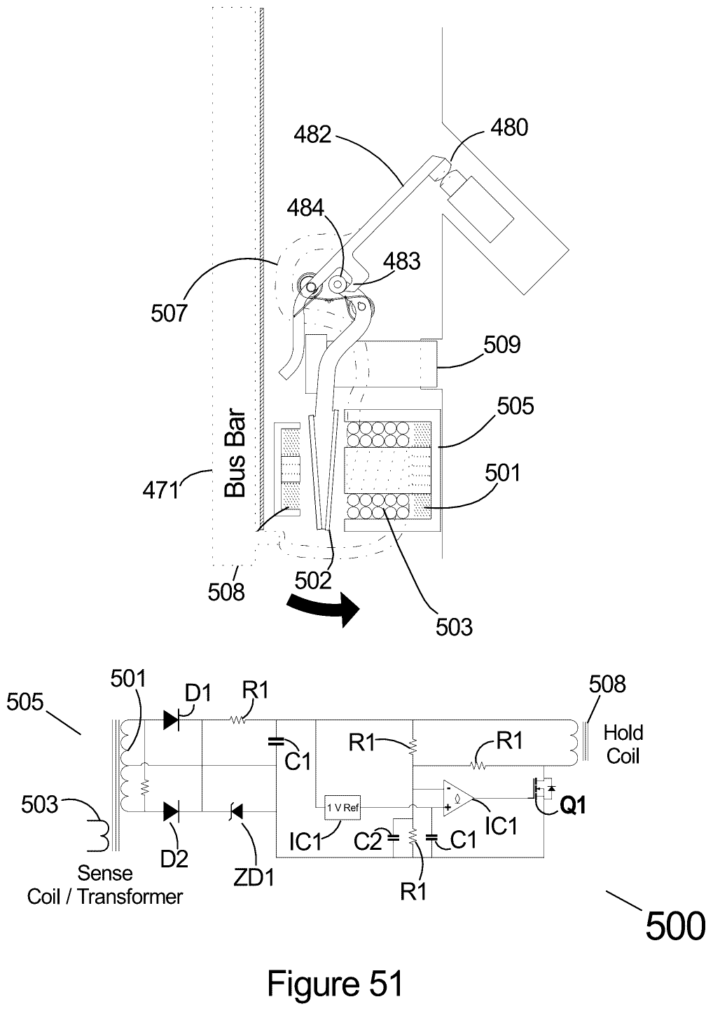

FIG. 51 depicts the moment of transition from the moment of having detected a current overload and before the circuit breaker disconnects the Contacts (480). The circuit breaker Moving Contact Arm (482) has not yet disconnected due to the progression of the release Pawl Roller Wheel (484) along the face of the Sear (4833) but it has not yet reached the point where the roller rounds the tip of the Sear (483). In this figure, the Pawl Roller Wheel (484) is right at the point of no return. As soon as it progresses any farther, the tip of the Sear (483) will round the end and the CB Moving Contact Arm (482) will be released.

It should be observed that at the point where the tip of the Sear (483) starts to round the end of the Pawl Roller Wheel (484), that action will force the continued rotation of the Pawl Lever (485) and thus move the Actuation Armature (482) even closer to the Sense Coil/Transformer Assembly (485).

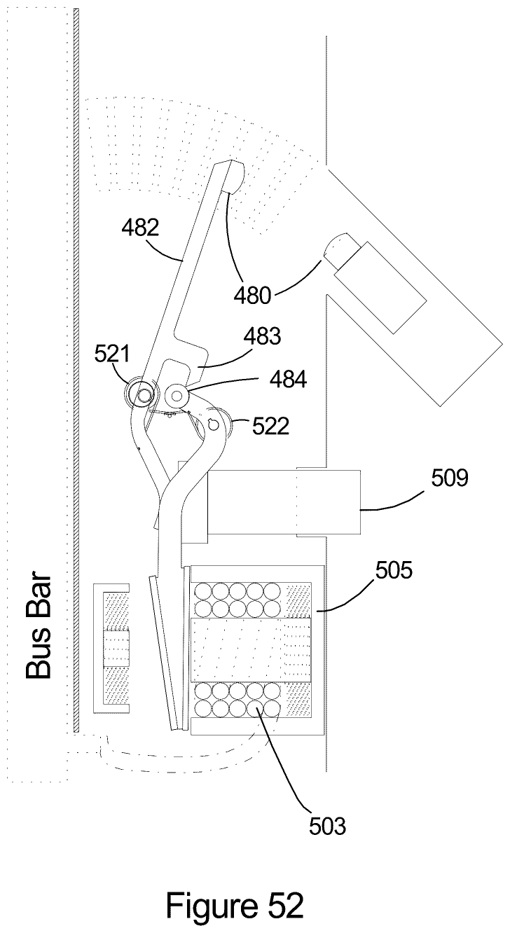

FIG. 52 shows the point where the circuit breaker Moving Contact Arm (482) is now in motion and the tip of the Sear (483) is rounding the end of the Pawl Roller Wheel (484). At this point, the contacts are disconnected and current through the circuit breaker stops. Current no longer runs through the Sense Coil/Transformer Assembly (503) and the magnetic field there ceases. Q1 remains “Off” and the hold coil has no power to it either. The Contact Arm Assist Spring (521) is now assisting the Moving Contact Arm (482) to continue to move towards the fully disconnected position (shown by arrow above the Contacts (480)). Also, at this point the back end of the Moving Contact Arm (482) is now pushing the Manual Reset Button (509) out.

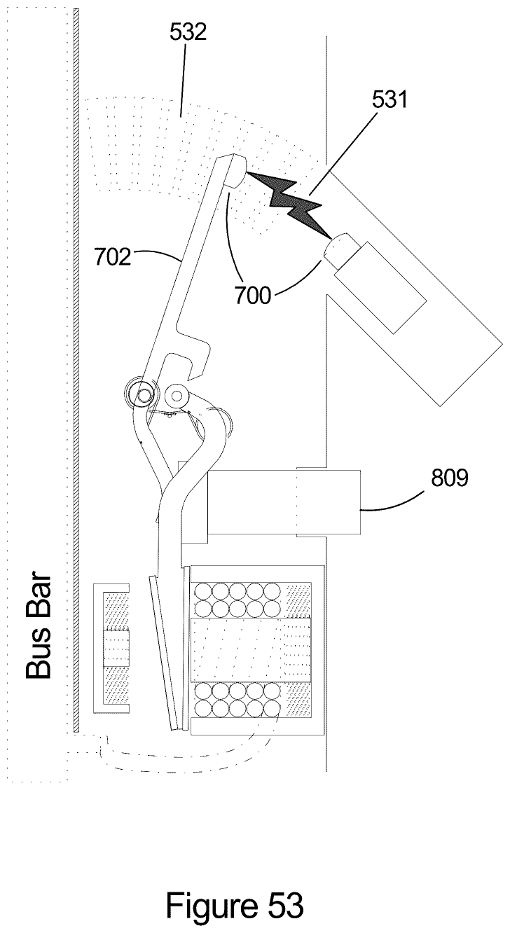

FIG. 53 shows the continuation of the disconnect action. The Contacts (700) are continuing to separate and the Moving Contact Arm (702) is continuing to increase the gap between the Contacts (700). If, in the event the over-current event that initiated this disconnect cycle was an event of very high current, such as a short in the connected equipment of the cord feeding that equipment, then the current can be very high. Current as high as several thousand amps is possible. Until a gap between the contacts becomes sufficient to extinguish the current flow, an Arc (531) can be sustained. This Arc can be causing vaporization of the surface of the contacts (700) and ejection of the hot gasses. Pressure can rapidly build and the ejected material needs to have a safe path to expand into. This Invention includes a set of vents (532) positioned along the side of the path of the moving contact at the end of the Moving Contact Arm (702) in the wall of the circuit breaker assembly. These vent into the un-occupied chamber of the adjacent Neutral or Ground connector bus-bar attachment channel. Because the chambers separate the current carrying pair of circuit breakers, there is no path for a cross arc to develop, even though the proximity of the two circuit breakers are relatively close. This design feature enables additional miniaturization of the assembly. Meanwhile, the Reset Button (809) continues to be pushed out.

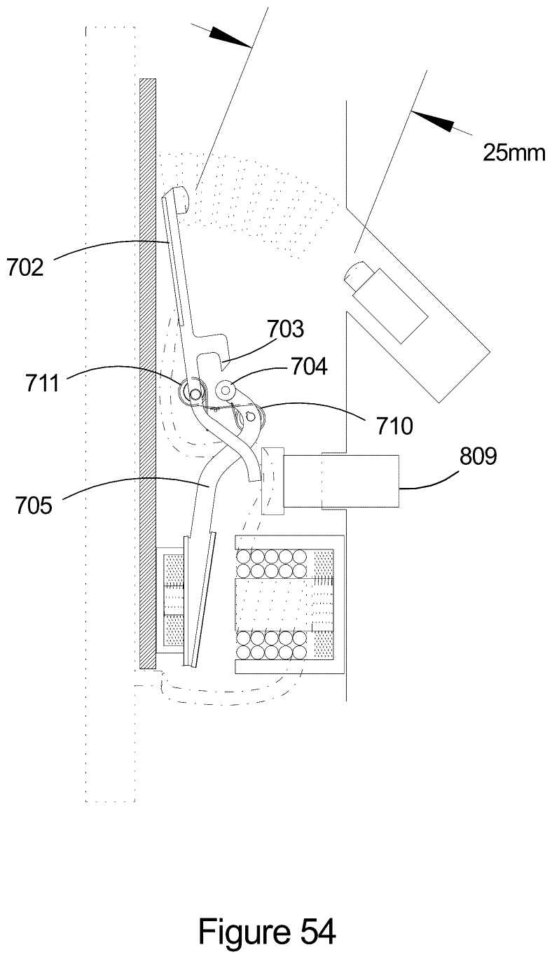

FIG. 54 shows the final resting position for the contacts after the complete opening of the circuit breaker. The Contacts are now separated by a gap of about 25 mm. This can be more or less depending on the desired IDC arc Current Minimum desired, but in this preferred instantiation 10 KA is the design criteria. When paired with the equivalent circuit breaker that is in series with this circuit breaker (always a circuit breaker in each of the electrical current carrying paths, and they are mechanically connected to one another), the Minimum IDC jumps to 20 KA. IDC is used instead of IAC due to the DC equivalent being the worst-case, and full disconnection in less than one half AC cycle.

For satisfying various Approval Agencies requirements such as Underwriters Laboratory (UL), or others, the final gap spacing for various applications can be adjusted as required by changing the dimensions of various components as required. Circuit breakers can get approval for use for a variety of applications, each with unique sets of requirements. This design can easily accommodate most of those variables.

Spring (711) is now holding the Moving Contact Arm (702) fully open in the maximum counterclockwise position (as viewed in this example). The Reset Button (809) is now out in a position where it can be used to reset the circuit breaker when desired. Armature Return Spring (710) has now returned the Pawl Lever (705) to its normal position where it can accept and latch the Moving Contact Arm (702) when it is returned to its normal position. At this point the circuit breaker is “tripped” and all current through it has ceased. It will remain in this condition until manually reset. Pushing the Reset Button (809) forces the Moving Contact Arm (702) clockwise and ultimately allows the Sear (703) to re-engage with the Pawl Roller Wheel (704) at which time the circuit breaker will be ready to pass current again.

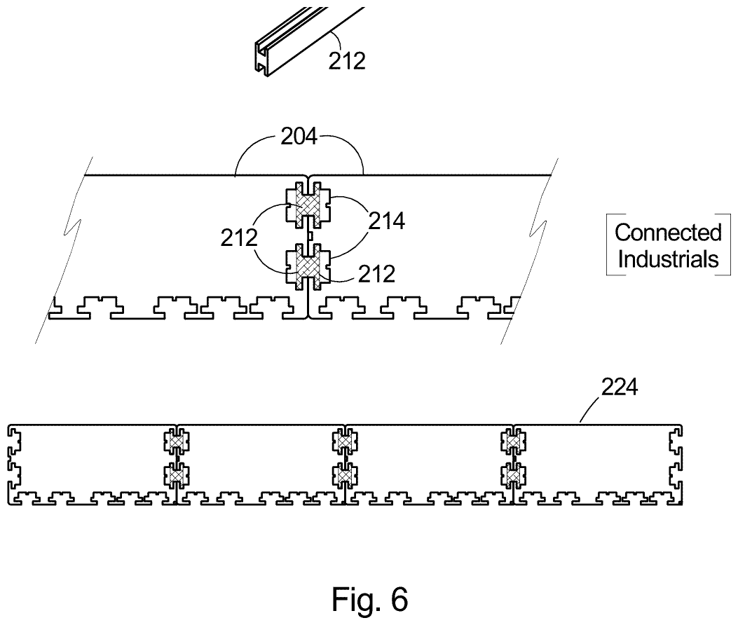

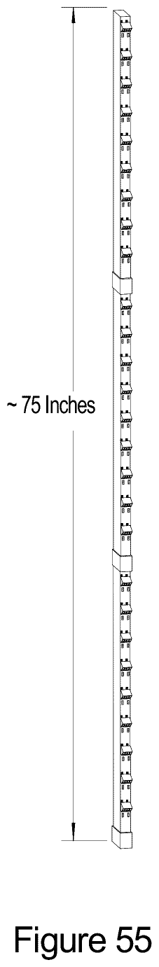

FIG. 55 shows an example of the desired maximum power delivery available with this invention as it fits in the vertical height limitation of approximately 80″ in a computer rack. The full three phase modules depicted in FIG. 6, each about 25″ in overall length are shown stacked in a group of three for a total of about 75″ overall. The feeder cords for all of these are not shown but can consist of four conductor 4-AWG 600 Volt Flat SO or SOW type cable. This configuration includes three groups of nine ea., 1200 VAC 20 Amp circuits for a total of 648 KVA power delivery to one rack. This is a major feature of this invention, and represents a very high level of power delivery capacity to any one given traditional computer room equipment rack.

FIG. 56 shows an example of an alternate organization of the circuit breaker modules in a horizontal configuration. There are cases in computer room power deployments where it is desirable to mount the power distribution in the rack and utilize horizontal distribution. This configuration can be observed as an alternate but does have a different means of distribution of the bus-bar power from the vertical configurations mentioned earlier. In a horizontal configuration, the busbar would likely be replaced with point to point and terminal block methods for distribution of the 60 Amp inputs to the individual circuit breakers.

FIG. 57 is an example of how the three Vertical Zero-U Mount 216 KVA3 Split 3 Phase 60 A 600 V Module with nine Receptacles could appear in an 80″ computer rack.

FIG. 58 demonstrates how a Horizontal configured 216 KVA3 Split 3 Phase 60 A 600 V Module with nine Receptacles might appear in a conventional 80″ Computer Room Equipment Rack.

It should be noted that the PSU+ATS described earlier can be designed to operate at high voltages, such as 600V or 1200V with the same basic methods described earlier. It can use the power distribution methods and apparatus described above. It can also use the high voltage plug and receptacle or plug and receptacle+interruptor or receptacle+circuit breaker apparatus described. The small form-factor of the cordcaps and receptacles is an important advantage so that the PSU or PSU+ATS can be built in common and space efficient form-factors and integrated into existing ITE server and equipment designs with minimal modifications. Some possible instantiations of the PSU+ATS have been described as to their form-factors and power delivery capacities above.

Data centers are typically designed and built to deliver A and B redundant input power sources to IT equipment racks. However, power distribution systems need maintenance, which usually requires downtime windows. Also, power distribution systems can fail, producing downtime. Two of the most common causes are human error and Un-Interruptible Power System (UPS) failures.

An IT device or other load with a symmetric power supply design will tolerate this downtime without any downtime or loss of performance. However, an IT device or other load with an asymmetric power supply design will not. It will either shutdown, or more likely stay up, but lose performance as discussed above.

The asymmetric design is more efficient and produces less electronic waste. However, there are some IT devices such as blade servers and especially Artificial Intelligence (AI) servers that are so expensive that any performance loss is very undesirable. These computers can cost more than $3 M, so they are much like supercomputers, where every second counts and can be billed at high rates of return. However, AI servers use very energy hungry Graphical Processing Units to do AI job processing, and this is already a pain point with data center energy consumption already one of, if not the fastest, growing energy usage causes. This affects energy production strategies and efforts to combat global climate change, which is critical. So, more efficient power supply designs are very desirable from that point of view.

ATS switches used in groups can solve this dilemma. ATS switches can be designed to be quite efficient, such as are described in this and the incorporated documents. By using a set of ATS switches in combination with an asymmetric power supply design, the loss in performance the asymmetric power supply design can impose when either the A or B power input source is unavailable can be avoided. This also avoids the presence of a single point of failure which use of a single upstream ATS switch would introduce. This is very important to operators of these types of IT devices because they have built and operate data centers that are designed to have redundant power distribution and do not like or trust configurations with a single point of failure.

The reliability gains from using multiple ATS units in parallel have been described in other filings but for the present matter it can be noted that the reliability equation is the chance that two or more of the parallel ATS units will fail in the time before the failure can be repaired. This is a very low probability. Also, IT device technology has advanced and almost all modern servers and many other IT devices have embedded microprocessors that run a separate management function that monitors the health of the device, including the power supplies and can monitor, alert and notify when a problem is detected. An example is the Dell IDRAC (Integrated Device Remote Access Controller) a baseboard management controller. These devices have separate connectivity such as an Ethernet port for example and can be used to monitor and even reset or power cycle the device. It can detect when a power supply has failed and/or its input power source is down.

The number of ATS switches to be used for a given asymmetric power supply design can vary. However, in all cases by auto-switching the input power to one or more of the power supplies in the device, sufficient power supply capacity can be made available to insure that the device operates at maximum performance levels. Typically, two or more ATS switches would be used to avoid the single point of failure issue described above.

We will now discuss methods for efficiently packaging and integrating into the rack parallel arrays of ATS switches.

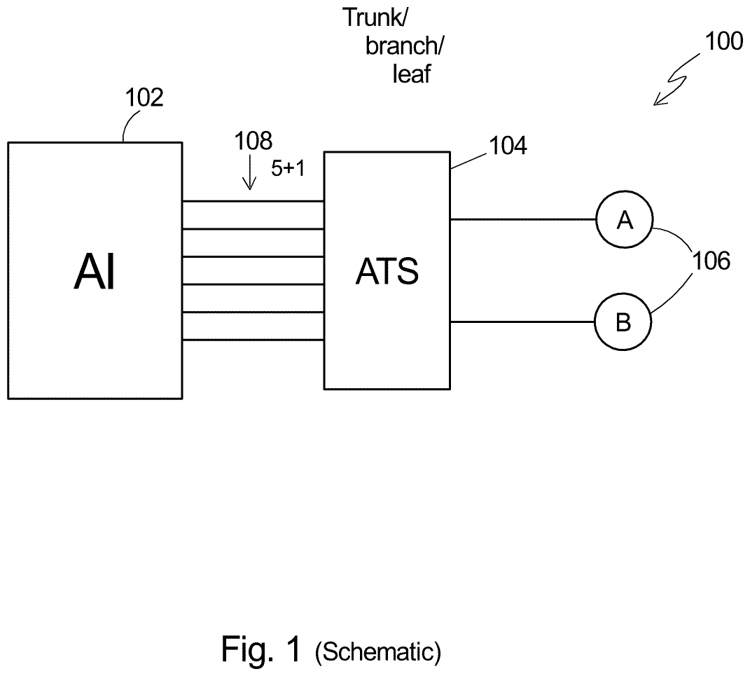

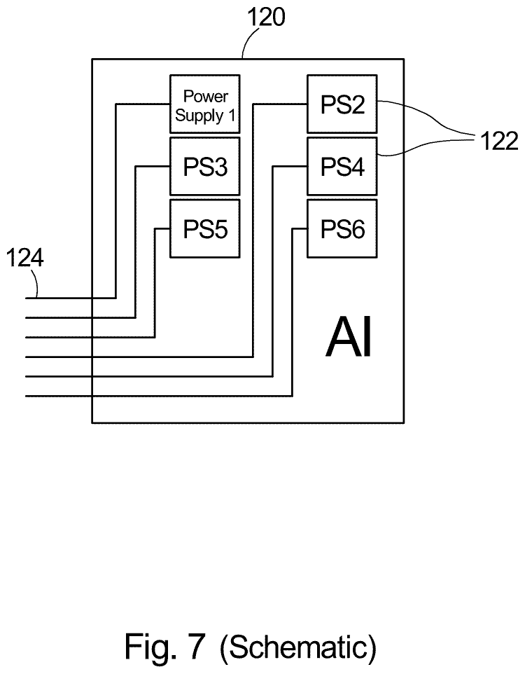

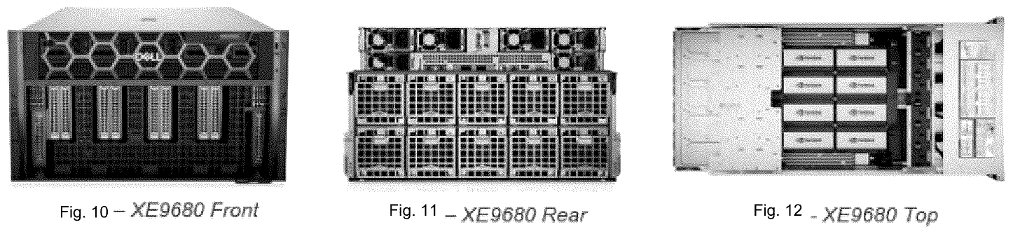

FIGS. 1-7 illustrate certain implementations involving the use of ATSs to provide efficiency and redundancy in relation to IT equipment with multiple internal power supplies. In the example below, this is primarily described in relation to AI servers 120 (see FIGS. 7 and 10-12) that, for example, require five power supplies for full performance but may include six power supplies 122 and six associated power ports for connecting six power cords 124 (i.e., a 5+1 system), which is an advantageous application of the invention. However, it will be understood that the invention is not limited to the illustrated context but is more broadly applicable to electronic equipment with multiple internal power supplies and sources, including symmetric and asymmetric systems with varying numbers of internal power supplies.

FIG. 1 is a schematic diagram illustrating a system 100 in accordance with the present invention. The system 100 generally includes an IT device 102, an ATS system 104, and power sources 106. For example, the device 102 may be a symmetric or asymmetric IT device such as a server. It will be appreciated that, for efficiency reasons as noted above, the present invention has particular advantages for asymmetric devices. In the illustrated implementation, the device 102 (see FIG. 1) is a 5+1 AI server that requires five internal power supplies for full performance and includes six internal power supplies, six power ports, and six power cords 108.

The ATS system 104 is operative to selectively connect some or all the power cords 108 to the A and B power sources. The A and B power sources, in the case of a data center, may include two independent power sources such as first and second power grid sources or a power grid source and an uninterruptible power supply (e.g., powered by batteries and/or diesel sources). In this regard, for some or all the cords 108, the ATS system 104 may switch from a primary source (e.g., grid power) to a secondary source (e.g., an uninterruptible power supply) upon detecting a degradation or interruption of the power signal of the primary source. In this manner, for example, if all six of the cords 108 are auto-switched, all six power supplies may remain available in the case that one of the sources is unavailable, even without any integrated source switching capability in the device 102.

A variety of types of ATSs and various positions of the ATS 104, as described in the incorporated documents, are possible in accordance with the present invention. In this regard, the ATS 104 may be positioned at a trunk, branch, or leaf of a data center power network as described in the incorporated documents, for example, in the data center rack housing the device 102, in another rack, at (or integrated into) a powered distribution system such as the Z-PDS marketed by Zonit, in a busway, or the like. The ATS system 104 may be a single unit such as the Z-ATS-MICRO (μATS™ or Micro), Z-ATS-IND, Z-ATS-MINI as described in the incorporated documents, or multiple units such as Z-ATS-Micro or Z-ATS-IND (Industrial) or Z-ATS-MINI of Zonit. The ATS unit or units can be single-phase power or polyphase power (three-phase is most common) capable. Multiple Zonit Z-ATS-MEGA root level ATS switches can also be used.

To monitor the status and function of one or more ATS units in the configurations described a number of methods can be used. The voltage, current, power quality, A to B and B to A transfers and other information can be monitored and reported by each individual ATS as described in the incorporated documents. This information can be used to report on the function of the group (both at an individual ATS level and at the group level) of multiple ATS units powering one or more IT devices (or other suitable loads) using communication, processing and reporting means described in the incorporated documents. Alternatively, a simpler method can be used which has advantages, especially for small form-factor ATS switches, such as Zonit designs and manufactures. A very simple method is to implement a state machine via dry contact monitoring of both the A and B inputs to an ATS. The dry contact circuits can infer the state of the device as follows. For the purposes of this example, the ATS units will be designed or set to prefer the A side input when it is present and of sufficient power quality.
1. A Present and B Present—The unit is operational on A power and B is available.
2. A Not Present and B Present—The unit is operational on B and A is not available.
3. A Present and B Not Present—The unit is operational on A and B is not available.
4. A Not Present & B not Present—The unit is down.

Using the above state information and the timestamps recorded when each state change was reported, the following can be known or be inferred using a very simple low-cost processing device.
1. The uptime of the device and the availability of each power source to which it is connected.
2. Which power source it is currently operating on.
3. When an A to B transfer took place.
4. When a B to A transfer took place.

The processing device can be incorporated into, be part of, or be separate from any of the devices described in the incorporated documents. It can communicate via wired or wireless means using a variety of communication transports and protocols, such as serial, Ethernet, TCP/IP (including specialized protocols that run on TCP/IP, for example SNMP and ModBus TCP), Bluetooth, WiFi and others. As described above, for ATS units in a group powering an IT device or other suitable load, the processing device can report on both each individual ATS or the group of ATS units. Such processing devices are now commonly available at low cost. It can report information to Zonit management and reporting devices, such as the Z-MMi (Z-IQ) or the Z-IQ-SUMMA, described in the incorporated documents. Those reporting devices can hold the group associations of the individual ATS units and then use that information to report individual and group ATS status and condition to advantage. It can be appreciated that this novel method allows the use of simple, low-cost and compact reporting methods and circuitry that can be incorporated into the ATS units described in the incorporated documents, a great advantage. The nature of dry contact monitoring makes the communication cabling necessary to implement this feature between the ATS units and the processing device or devices very minimal a significant advantage. Also note that this cabling and the power and voltage levels used in the dry contact circuits can be selected to be radio frequency (RF) noise resistant (twisted pair or braided communication cabling can be used for this purpose), a great advantage, since when ATS units transfer the arcing that can occur across their relays can be a source of significant RF noise bursts.

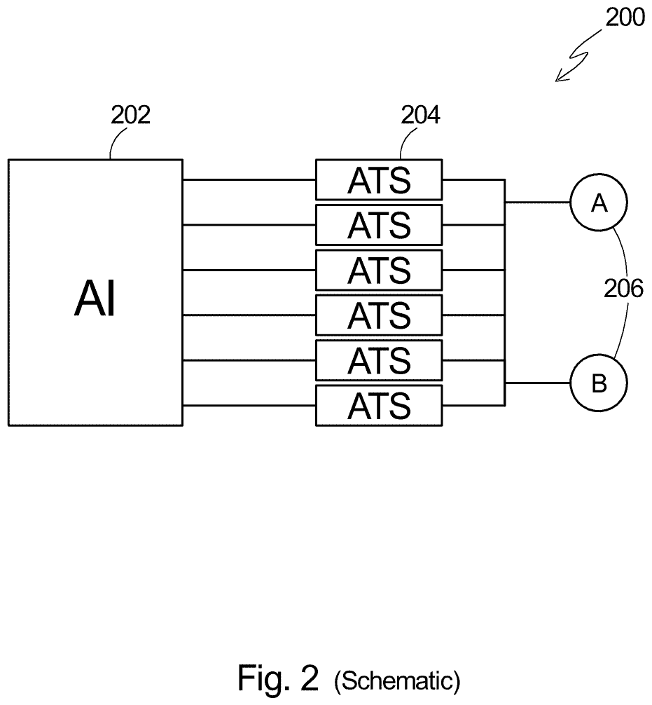

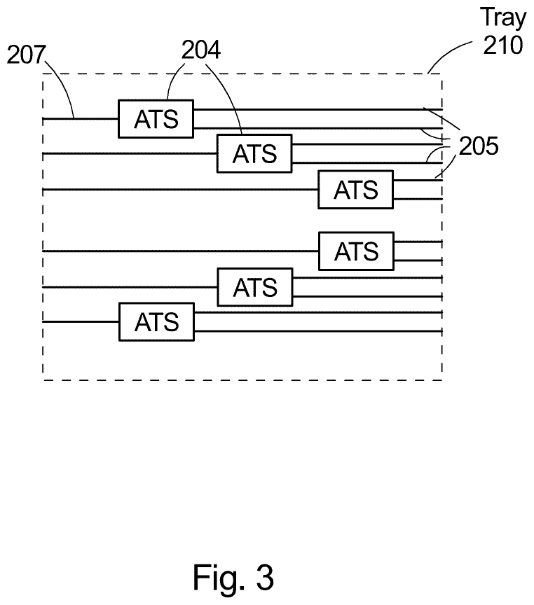

As shown in FIGS. 2-3 a preferred implementation of a power supply system 200 involves using one Z-ATS Industrial unit 204 per power cord 208 of the device 202. The Z-ATS Industrial is suitable for high current/power applications, such as supporting power supplies for AI servers, and provides advanced functionality as described in the incorporated documents. Each ATS 204 includes two inputs 205, one from each of the sources 206, and one output 207 connected to a power cord of the device 202. As shown, the ATSs may be interconnected to form a tray 210 of (in this example) six ATSs to support each device 202. The interconnected ATSs may be offset from one another, e.g., in a wedge configuration, to facilitate viewing of LEDs and access to communication ports and other features. It will be appreciated that the dimensions of the ATS units enable them to be positioned side-by-side within a single U or 2U of the rack. Adjacent ATSs may be interconnected via a connector 212 (FIG. 6) extending between T-slots 214 of adjacent ATS units 204. The T-slots are described in more detail in the incorporated documents. Alternatively, the ATS units 204 may be oriented in an edge-wise, vertical configuration or other configurations as convenient. Alternatively, individual Z-ATS Industrial units may be attached to DIN rails or other attachment points, e.g., at different U's of a rack, as described in the incorporated documents, when space permits.

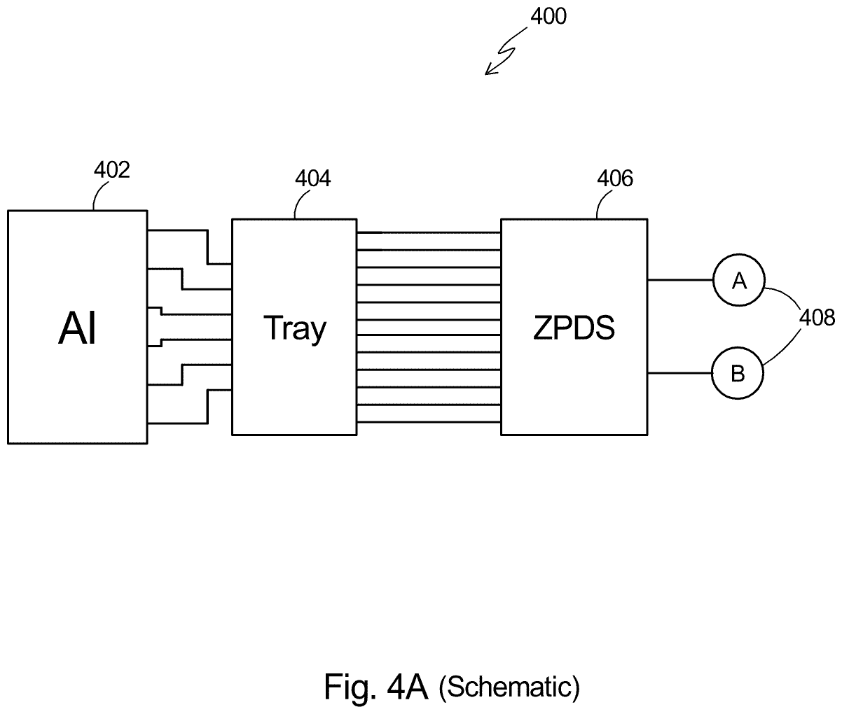

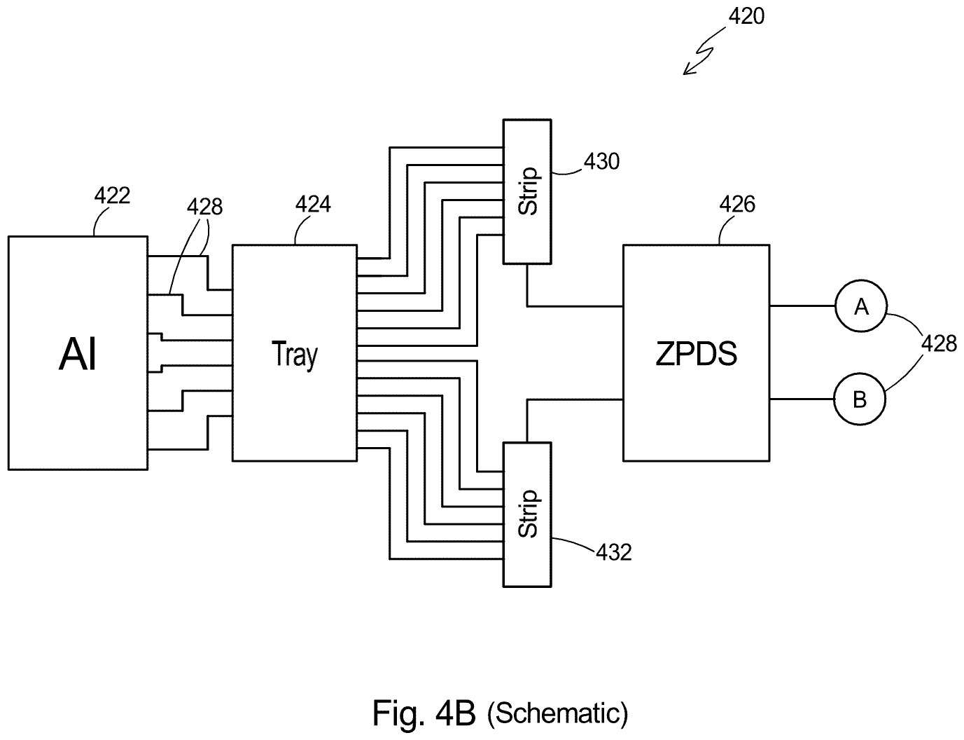

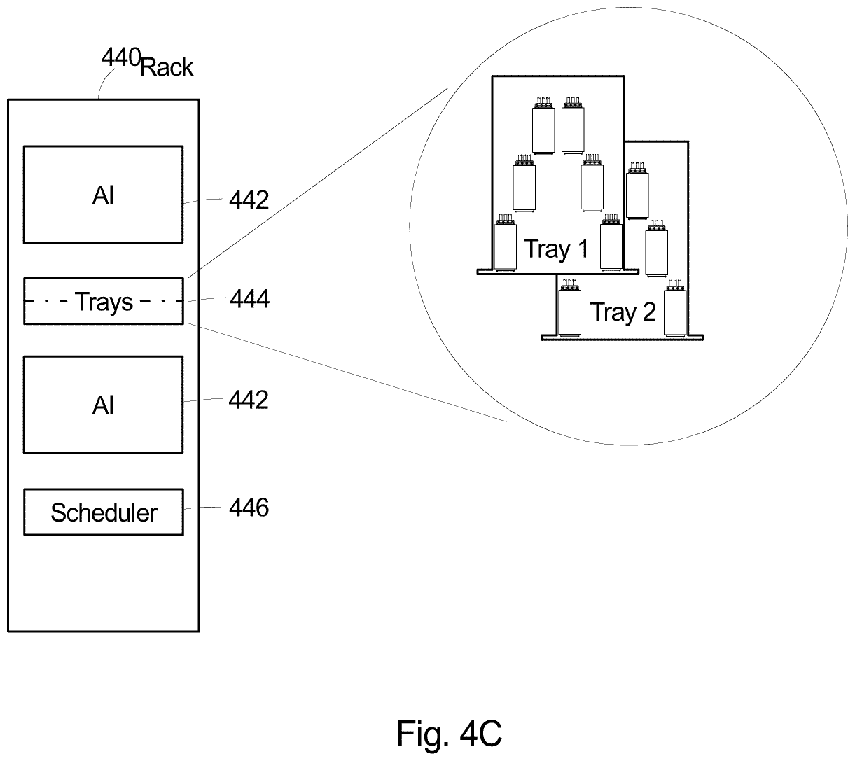

FIGS. 4A-4B show two (of many possible) configurations of power supply systems incorporating such trays of ATSs. In the system 400 of FIG. 4A, a tray 404 of ATSs is positioned between a device 402 and a PDS 406. The PDS 406 is connected to two power sources 408. The PDS 46 may provide three-phase power, e.g., separated by a phase angle of 120°, as described in the incorporated documents. For example, the PDS 46 may be the Z-PDS of Zonit.

FIG. 4B shows an alternative system 420, where the PDS 426 supplies power from sources 428 to two power strips 430 and 432. For example, strip 430 may provide three-phase power (via different outlets) from source A and strip 432 may provide three-phase power from source B. The strips 430 and 432 may be, for example, vertical plug strips located in appropriate parts of the rack or may be incorporated into a single or multiple horizontal “arrowhead” power distribution units occupying a 1 U or more of the rack. The input cords of a tray 424 are connected to the strips 430 and 432 (such that each ATS has an A input and a B input) and the outputs from the tray 424 are connected to the power cords 428 of the device 422.

FIG. 4C shows an example of a layout of a rack for a plurality of rack units in accordance with the present invention. The illustrated rack includes two multi-power supplied devices 442 such as AI servers. A 5+1 power supply AI server may occupy about 6 U's of the rack 440. Trays 444, as described above, to support the devices 442 may be positioned adjacent to (e.g., between) the devices 442 to minimize cabling. For example, multiple trays (e.g., one tray per device) may be arranged front-to-back in a single U (or multiple U's) of the rack 440 as depicted in the top-view insert of FIG. 4C. The trays 444 may be connected to a PDS (or an array of PDSs as described in the incorporated documents) located in the rack 440 or separately. To further reduce and organize cabling, the power cords can be gathered and dressed using ties or the like. Additionally or alternatively, Hydra power cords or Z-Strips or other power distribution apparatus, as described in the incorporated documents, can be employed between the PDS and the trays and/or between the trays and IT devices depending on the specific configuration.

The illustrated rack 440 further includes a scheduler 446. The scheduler 446, which may be embodied in a computer/server or other data device, schedules jobs for the devices 442. In this manner, use of the valuable (and expensive) resources of the devices 442 can be optimized. Although not shown, it will be appreciated that the rack 440 may include a variety of other devices such as PDSs, switches, storage units, power strips, network connections (e.g., provided via a Netstrip as described in the incorporated documents), sensors (e.g., for security, environment, and power), cooling systems, and the like.

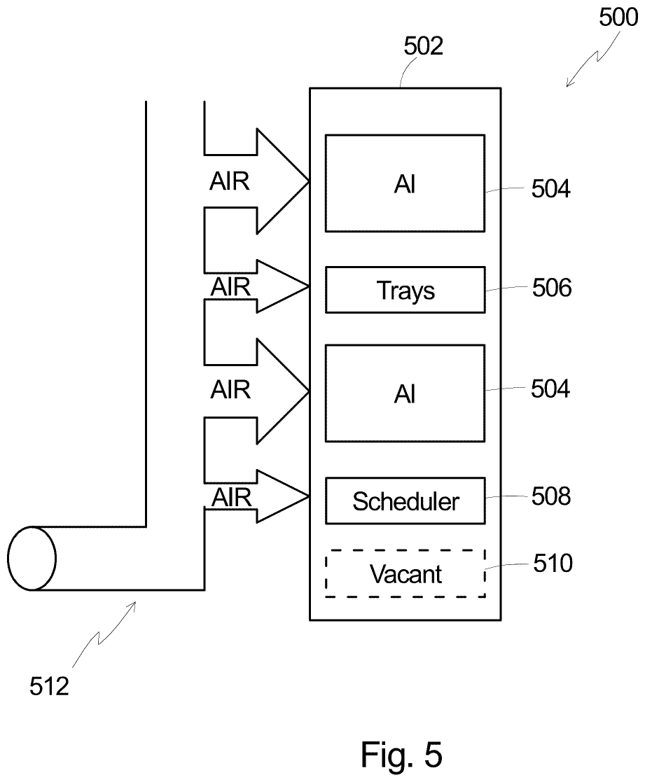

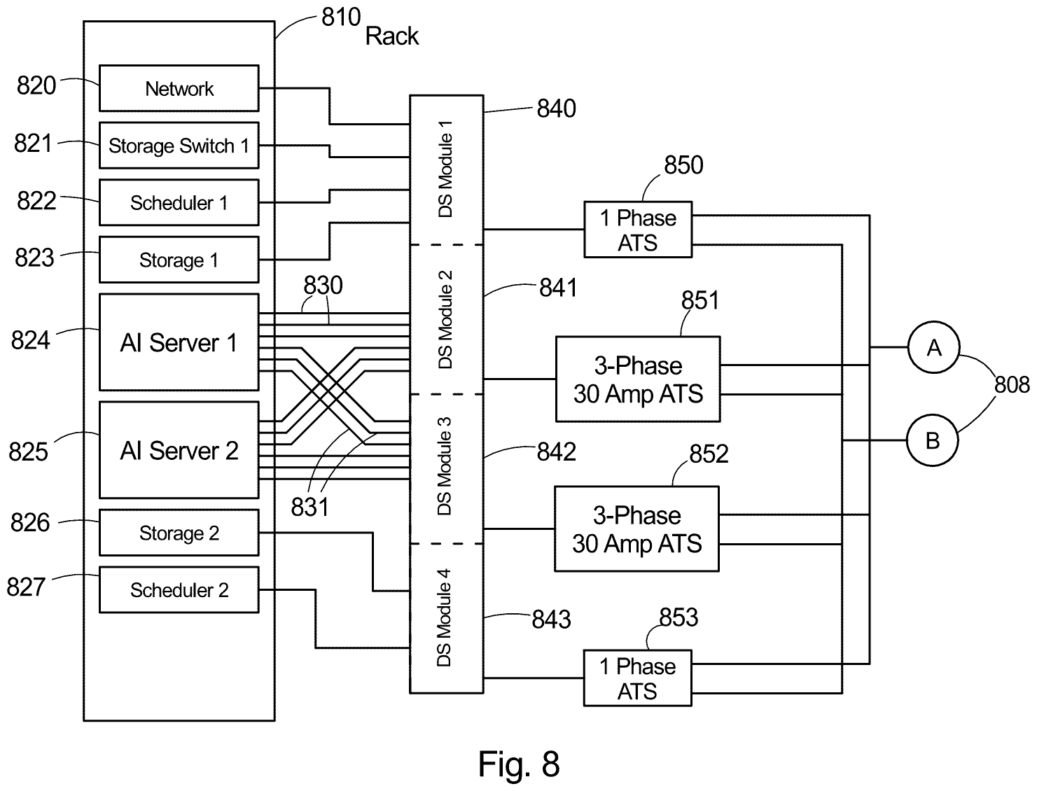

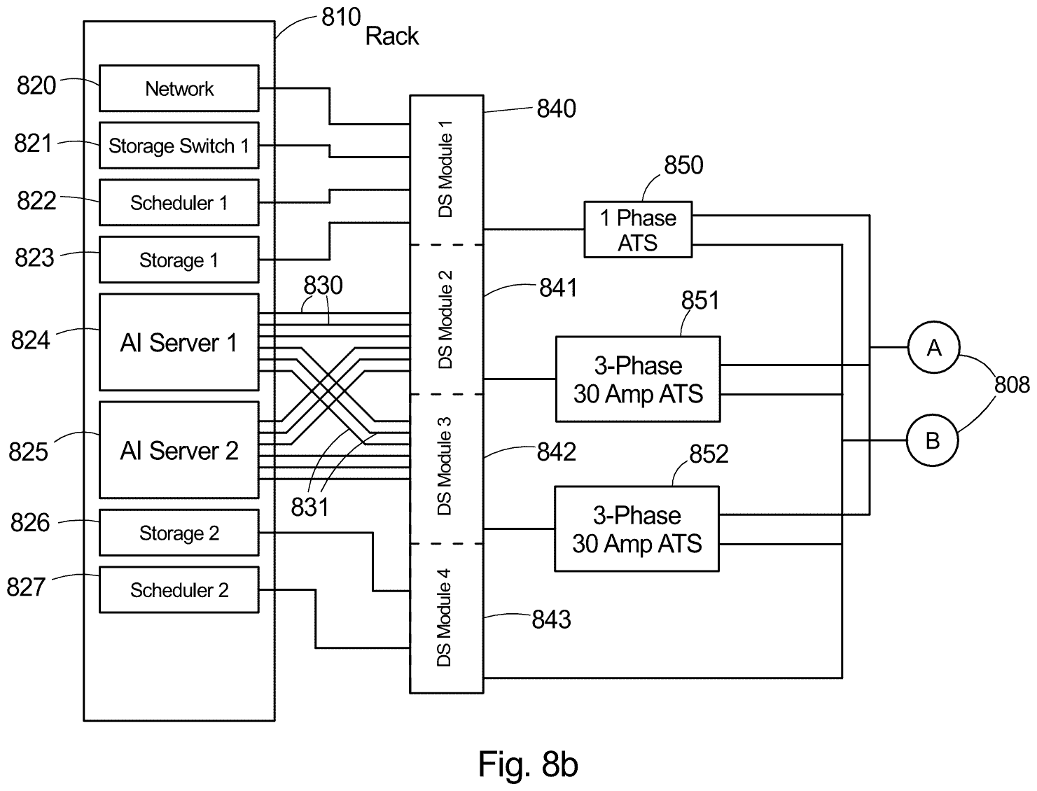

FIG. 8 and FIG. 8b show examples of a layout of a rack similar to rack 440 that is powered by a Zonit Double-Shot power distribution device. The Double-Shot has unique characteristics well suited to this application. Each segment of the Double-Shot can be independently powered as described in the incorporated documents. The power for each segment can be auto-switched using a variety of ATS switches both single-phase and three-phase (or multi-phase) such as the Z-ATS-MICRO, Z-ATS-IND, Z-ATS-MINI, Z-ATS-MEGA or others described in the incorporated documents. The power for some segments of the Double-Shot can not be auto-switched if the application does not need that, saving expense. This allows matching the power levels and requirements of each segment of the rack described in FIGS. 5, 8, and 8b to the ATS switch (or non-switched power source) that feeds that segment of the Double-Shot. This provides great flexibility and minimizes rack volume and cabling lengths. It can also be used to insure that multiple independent power paths that are auto-switched (or not) can be provided as needed to any IT device in the rack in either single-phase or three-phase in the amperages and voltages required. It also can be used to minimize the number of circuit breakers used in the power panels feeding the Double-Shot saving circuit breaker positions in the panel which can be a great advantage.

It is also possible to use the same basic idea and invert it such that the ATS switches are fed by the Double-Shot and not feeding it. This can be useful for using rack mounted ATS switches or ATS switches incorporated into rack mounted power distribution devices such as the Z-PDS or Arrowhead as described in the incorporated documents. Each segment of the Double-Shot can be fed by or feed an ATS unit or an IT device as is required. It also allows for some or all of the ATS switches to be located outside the rack if needed or desired. The IT device being powered can be fed from different segments of the Double-Shot effectively interleaving the power feeds for redundancy and increased reliability. Multiple Double-Shot devices can be used to also interleave two or more power sources to a given IT device or other suitable load. The combinations available with this apparatus and methods provide maximum flexibility in power distribution. Both auto-switched and non-auto-switched, redundant and non-redundant power paths can be provided while using a minimized amount of rack space. Any combination needed of these characteristics can be easily configured to meet the application needs and requirements.

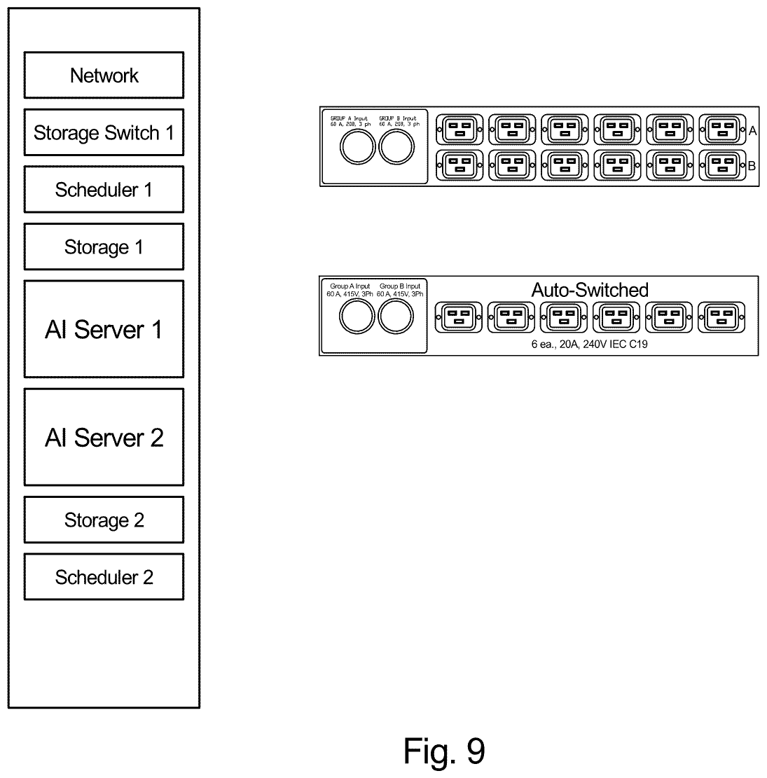

FIG. 9 shows a Z-PDS power distribution system unit that has had multiple ATS units incorporated into its enclosure. Note that the method described can also be used with the Zonit Arrowhead. The ATS units can be single phase or three-phase or mixed as required. The auto-switched output receptacles of the Z-PDS unit can be three-phase or single-phase or a mix as required for the application. A mix of auto-switched and non-autoswitched receptacles can also be used if needed for the application. Two single phase examples are shown in FIG. 9, one with non-autoswitched output single-phase receptacles and the other with auto-switched single-phase output receptacles. This instantiation has several advantages, such as integrated packaging, minimizing external cabling, offering auto-switched three-phase or single-phase output receptacles, allowing standard power cord and locking power cords to be used which is useful to accommodate equipment mounted at varying heights in the rack. The ATS units can be also be designed to be hot-swappable modules such as is commonly done for server power supplies. This offers the advantage of being able to swap out a failed ATS module without downtime. This also would not cause a throughput loss to an AI server with an asymmetric power supply design that was N+X where X is one or more. The ATS units can be monitored and managed as described in this and the incorporated documents.

Certain devices, such as AI servers, generate significant heat in operation. Conventionally such devices may be cooled using water (or other liquid or gas coolant)-based cooling systems. However, water in the vicinity of high-power electronics is a hazard and the plumbing associated with configuring and reconfiguring racks is complicated. An alternative cooling system 500, in accordance with the present invention, is depicted in FIG. 5. The illustrated system 500 includes a rack 502 containing devices 504, power trays 506, and a scheduler 508 as described above. The rack 502 may also include vacant spaces (U's) as indicated at 510. Of course, the rack 502 may include other equipment as described above.

In the illustrated embodiment, the system 500 further includes an air-based cooling assembly 512. The assembly 512 provides pressurized, cooled air to the equipment (504, 506, 508) in the rack 502. For example, the assembly 512 may be provided via a modular, air-based cooling system as described in the incorporated documents. Preferably, the assembly 512 delivers a directed, cooling air supply at an individual U or U's of the rack 502. The volume of cooling air provided in each rack location can be controlled by valves at those locations and can be varied by location depending, for example, on the needs of specific pieces of equipment (including no air at certain locations such as vacant locations). The valves may be controlled based on feedback from local sensors such as temperature, pressure, and/or current/power sensors. These sensors may be connected to intelligent ATSs including data communication ports and processing components as described in the incorporated documents.

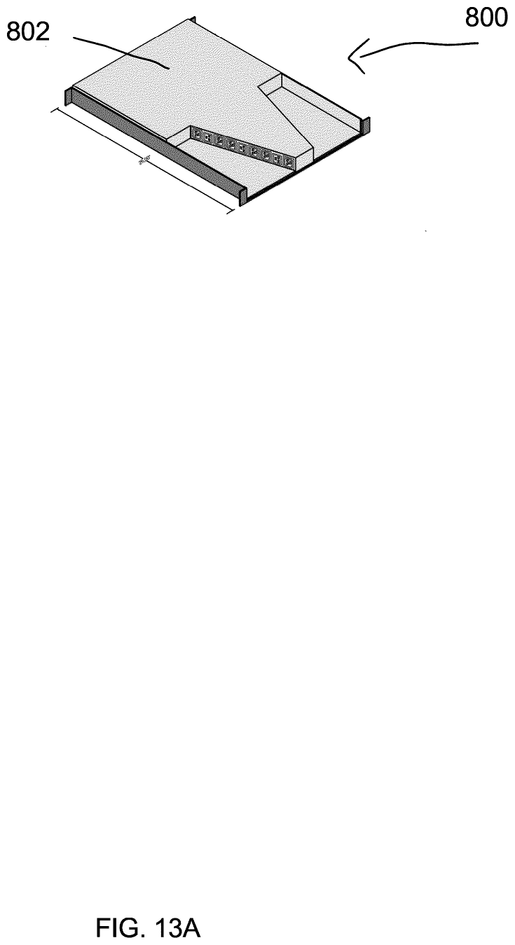

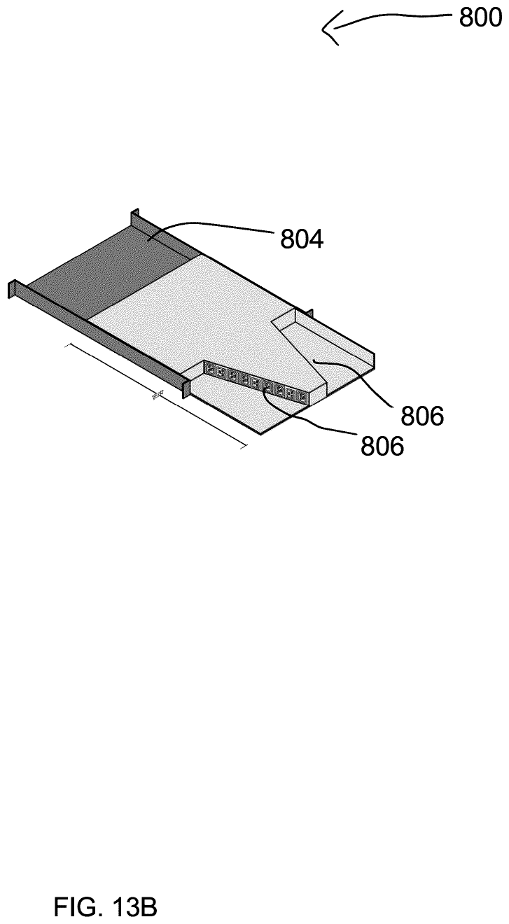

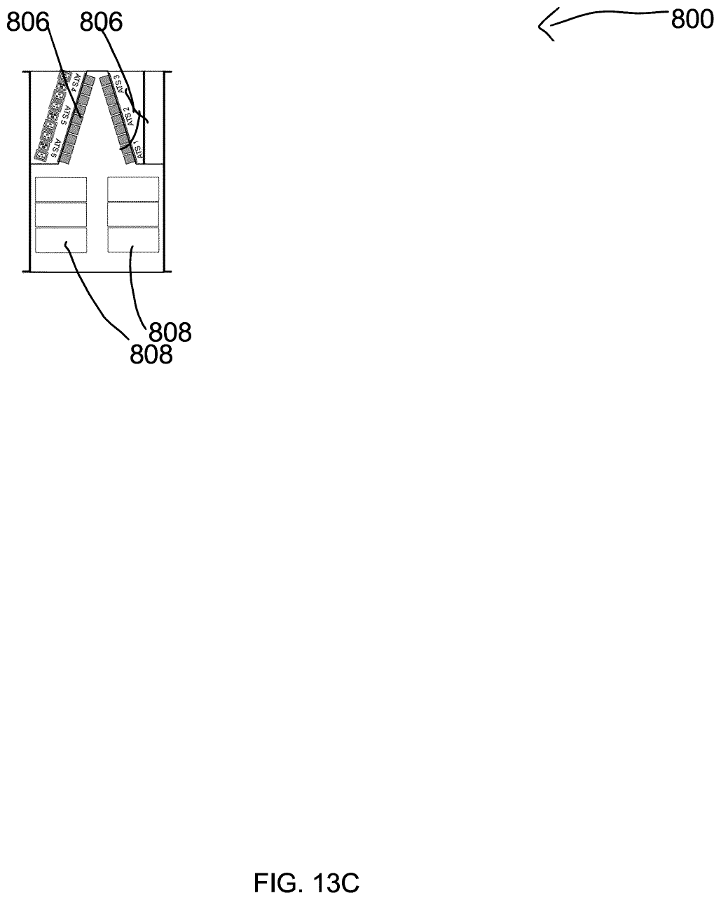

FIGS. 13A-13C illustrate a further embodiment of a power tray 800 in accordance with the present invention. FIG. 13A shows a perspective view of the tray 800 in a retracted position, FIG. 13B shows a perspective view of the tray 800 in an extended position, and FIG. 13C is a top, schematic view of the tray 800.

The tray 800 generally includes an arrowhead power supply unit 802 retractably mounted in a chassis 804. The unit 802 is movably mounted in the chassis 804 to move between the retracted and extended positions as shown. Preferably, the unit 802 can be secured in each of the extended and retracted positions. For example, one or more bolts, detents, latches, or the like may extend between the unit 802 and the chassis 804 (e.g., between respective flanges thereof) to releasably secure the unit 802 in each of the extended and retracted positions. The chassis can be integrated with any of the Universal Cabinet System mounting mechanisms described in the incorporated documents including, for example, the UCAB case.

The chassis 804 is dimensioned to be received within an equipment slot or space of an equipment rack. In this regard, the power tray 800 is preferably dimensioned to fit within a 1 U or 2 U (1 U=1.75 inches) space and the width and length of the chassis 804 are selected to fit within a standard rack. For example, the length of the chassis 804 and unit 802 may be about 26 inches and the width may be about 19-23 inches, depending on the rack implementation. The illustrated chassis is about 19 inches wide. The chassis 804 further includes mounting flanges for bolting to mounting rails of the rack. Alternatively, the chassis may be adapted to mount to the rack using a mounting kit, one example of such is as described in U.S. Pat. No. 11,895,800, which is incorporated herein by reference.

The unit 102 includes a number of Automatic Transfer Switches (ATSs) 808 as described in this and the incorporated cases. Generally, each of the ATSs 808 has two electrical power inputs, e.g., from an A source and a B source, and one power output. For example, one of the power sources may be a traditional utility power source and other may be from an uninterruptible power supply (UPS). As described in the incorporated cases, each ATS 808 monitors the power quality from a current power source and automatically switches to the other power source if the power is interrupted or the power quality becomes degraded. The power output of each ATS 808 powers a load. In this example, each of the outputs may be connected to a power supply of a high-power IT device such as an AI server. In this manner, each internal power supply of a six-power supply AI server is supplied with redundant power with no single point of failure and a much lower probability of failure, since two or more of the ATS (depending on the power supply design details) units would need to fail in a time window that was too short for the 1^{st} ATS failure to be detected and repaired. That is very statistically unlikely. For example using a 300 k MTBF value and a four hour MTTR window results in a the probability of two units NOT failing in the 4 hour time window being equal to 99.999999988314%!

The A and B input power to each ATS 808, as well as the output power from each ATS 808, may be connected to the A and B power sources and the equipment, respectively, via power ports 806. The ports 806 are located near the backside of the tray 800 for convenient access to power strips or other power supplies that are typically accessed from the back of the rack. The ports 806 are provided in a wedge-shaped extension that provides an enlarged area for easy access to the ports 806 in the extended position of the tray 800. This form-factor and its advantages have been described in the incorporated cases, but to summarize, a key advantage of this form-factor is that is provides more surface area (than a typical square or rectangular form-factor) on the side panels of the enclosure which are in the form of hypotenuses of the two right triangles making up the Arrowhead (FIG. 13C) to mount receptacles and other components needed for it to function, which is very useful in minimizing the height of the unit to the minimum number of rack units, which is desirable, as rack space is very expensive. It should be noted that the form-factor can be “mirrored” back-to-back in which case the “Arrowhead” triangular form-factor with two hypotenuses available for component mounting becomes a “Diamond” form-factor (FIG. 13C) with four hypotenuses available for mounting components. Further, the angles of the hypotenuses can be varied as needed and the tip of the two (or four) right triangles can be cut off to make a smaller flat surface suitable for status indicators, power inputs or other needed components. An example of this is shown in FIG. 13A, where the flat surface is shown but not populated.

Accordingly, three power ports 806 (two input and one output) may be provided per ATS 808. As shown in FIG. 13C, the power ports 806 may be organized by ATS unit and may be clearly marked, for example, as “ATS1 A,” “ATS1 B,” and “ATS1 out,” and so forth for the other ATSs 808. Although not shown, it will be appreciated that appropriate cords or other electrical connections may be provided between the ports 806 and the ATSs 808. The ATS units can be single-phase or three-phase or poly-phase as needed for the application and the connectors used can appropriate to the power type. Accordingly, the invention can function as an auto-switched power source with power coming from other Power Distribution Units in the rack, such as vertical or horizontal plugstrips, or as an integrated PDU that combines the power distribution function with the auto-switching function, such as described in the incorporated documents for other form-factors such as the ZPDS-ATS with one or more ATS units incorporated into its enclosure.

Furthermore, many of the devices described in this and the incorporated documents can perform passive electrical phase-load balancing via controlled connection of loads to the device in question, which is done by providing the end-user specific instructions (specific to each device and load configuration, but able to be described in a deployment guide with specific instructions for each usage scenario) on how to correctly connect loads to the outputs provided by each device. This is very useful when using polyphase input power sources to balance the net total load on each of the power inputs. This happens statistically over a set of these devices as described in the incorporated documents including, for example, in the Power Methodology case.

The tray 800 may further provide network access (e.g., via ethernet, fiber optics, USB, or the like) for rack equipment as generally described in the Management Module Case. Appropriate ports for such access may be provided adjacent to the ports 806, on the front of the tray 800, or another location. In addition, various displays or indicators may be used to provide an indication to users of status information such as power state, which power source is currently being used for each ATS, etc. For example, each ATS 806 may have indicator LEDs for “on A,” “A on,” “on B,” and “B on,” for a total of four LEDs per unit (24 LEDs total). Other LED indicator counts and locations are possible as needed.

The units 802 may have functionality as generally described in U.S. Pat. No. 8,907,520, though the number, configuration, capacity and features of the ATS units used can be chosen to meet the specific application requirements and fit in a one or more units of rack space. Therefore, different ATSs may be used as required (either in identical or different capacities, ratings and features). The unit can be mounted to be retractable, and the unit can be designed for use with high-power equipment such as an AI servers, among other changes. However, referring to the attached patent, a method and apparatus are provided for distributing power via receptacles (or hard-wired output cords) as is shown in FIG. 5 of that patent. In the described instantiation, that apparatus has two power inputs, one from an “A” source, the other from a “B” source. The amperage of the “A” and “B” power sources can be chosen to match the number of auto-switched output receptacles and their anticipated average and/or maximum power draw. The apparatus takes input power from the “A” and “B” sources and distributes it to a number of Zonit Micro Automatic Transfer Switch Modules contained in the enclosure (either as separately deployed modules or modules combined onto one or more printed circuit boards) of the apparatus. The “A” and “B” power sources may be DC or AC single phase, split-phase or three-phase, but in a preferred instantiation, both would be of identical types. Each of the Zonit Micro Automatic Transfer Switch Modules feeds an output receptacle (or hard-wired power cord) located on the face of the enclosure of the apparatus. Two or more circuit breakers, optionally with visual power status indicators, may be provided to allow disconnecting the unit electrically from the branch circuits that feed it. Additional “Virtual Circuit Breaker” control switches and indicators may also be included to provide a means to disconnect end-user equipment from individual Zonit Automatic Transfer Switch modules. The apparatus can be mounted within the rack or on top of it or on its side. The size of the enclosure can be minimized due to the very small form factor of the Zonit Micro Automatic Transfer Switch. It can contain a multiplicity of Zonit Micro Automatic Transfer Switch (“Zonit ATS”) modules within an enclosure that is no more than two NEMA standard rack units (1 U=1.75″) in height. For example, twelve or more ATSs, each having a power density of 2 kilowatts per 10 cubic inches, can be disposed within 1 or 2 U of the rack, depending on the depth of the rack. The Zonit μATS modules can be constructed as separate or combined circuit boards to optimize ease and cost of manufacture. Although the enclosure takes up rack space, by eliminating the need for in rack plugstrips, which are usually mounted vertically in the rack, data center floor space can be optimized as follows. The NEMA standard equipment width that is most commonly used is 19″.

Most NEMA standard racks for 19″ equipment are around 27″ wide to allow adequate space to mount a variety of vertical plugstrips in the sides of the rack. These plugstrips (also sometimes called power distribution units or PSU) do not have industry standardized dimensions, so it is difficult for equipment rack manufactures to optimize their rack dimensions for all available vertical plugstrips. Therefore, the total width and depth of the rack determines its floor area usage. By eliminating the need to run anything but power cords and network cords down the sides of the rack (or optionally down the back of the rack), it is possible to specify racks with smaller outside dimensions, down to a width of approximately 21″ and a depth of approximately 2-3″ more than the deepest IT equipment to be mounted in the rack. This is more space efficient. If for example, 24″ racks (which align nicely onto the 2′×2′ floor tiles used in most raised floors) are used vs. 27″ racks, then one additional 24″ rack can be deployed in a row of 8 racks. This is a significant gain in data center floor space utilization.

The foregoing description of the present invention has been presented for purposes of illustration and description. Furthermore, the description is not intended to limit the invention to the form disclosed herein. Consequently, variations and modifications commensurate with the above teachings, and skill and knowledge of the relevant art, are within the scope of the present invention. The embodiments described hereinabove are further intended to explain best modes known of practicing the invention and to enable others skilled in the art to utilize the invention in such, or other embodiments and with various modifications required by the particular application(s) or use(s) of the present invention. It is intended that the appended claims be construed to include alternative embodiments to the extent permitted by the prior art.

1. A method for supplying power to electronic equipment, comprising:
providing a piece of electronic equipment including multiple internal power supplies, each said internal power supply being associated with a power port for receiving power from an external source;
providing an automatic transfer switching system, separate from said piece of electronic equipment, for receiving input power from first and second power sources and selectively providing output power to a load via one or more output ports; and
connecting, via power cords, a plurality of said power ports of said piece of electronic equipment to said one or more output ports of said automatic transfer switching system.

2. The method of claim 1, wherein said piece of electronic equipment has a first number, M, of said internal power supplies and requires a second number, N, of said internal power supplies to be operative for supplying power for said piece of electronic equipment to be fully functional, where N is greater than M/2.

3. The method of claim 2, wherein M is at least six and N is at least five.

4. The method of claim 1, wherein said automatic transfer switching system is operative for switching from outputting power from said first power source to outputting power from said second power source responsive to one of a power signal degradation and a power signal interruption of a first power signal of said first power source.

5. The method of claim 1, wherein said automatic transfer switching system comprises multiple automatic transfer switches, each of said multiple automatic transfer switches being operative for receiving input power from said first and second power sources and selectively providing output power to a load via one or more output ports.

6. The method of claim 5, wherein a number of said multiple automatic transfer switches is at least equal to a number of said plurality of said power ports of said piece of electronic equipment.

7. The method of claim 6, wherein said number of said plurality of power ports of said piece of electronic equipment is equal to a number of said multiple internal power supplies.

8. The method of claim 5, wherein said multiple automatic transfer switches are interconnected to form a power tray.

9. The method of claim 8, wherein said power tray has a dimension of no more than 2 U's.

10. The method of claim 8, wherein said power tray has a dimension of no more than 1 U.

11. The method of claim 8, wherein each of said automatic transfer switches has one or more visual indicators on a first side thereof and said automatic transfer switches are interconnected such that said first sides of said automatic transfer switches are offset from one another.

12. The method of claim 11, wherein said automatic transfer switches are interconnected to form a wedge shape.

13. The method of claim 8, further comprising disposing said piece of electronic equipment and said power tray in an equipment rack.

14. The method of claim 8, further comprising disposing two pieces of electronic equipment, each including multiple internal power supplies, and two power trays in an equipment rack.

15. The method of claim 14, wherein said two power trays occupy a space of no more than 2 U's in said equipment rack.

16. The method of claim 15, further comprising disposing said two power trays between said two pieces of electronic equipment in said equipment rack.

17. The method of claim 1, further comprising providing an air-based cooling system for said equipment rack, said air-based cooling system being free of any liquid coolants at said equipment rack.

18. The method of claim 17, wherein said air-based cooling system provides different airflows at different locations of said equipment rack.

19. The method of claim 18, wherein said air-based cooling system further comprises multiple valves for controlling said airflows based on a control signal.

20. The method of claim 19, wherein said control signal is based on information from a sensor disposed in said equipment rack, said sensor operative for sensing one of a temperature, a pressure, and a power usage in said equipment rack.

21. The method of claim 1, further comprising providing a power distribution system interposed between said automatic transfer switching system and said first and second power sources.

22. The method of claim 1, further comprising providing multiple power distribution system devices associated with a first power port of said multiple power ports.

23. The method of claim 1, further comprising providing multiple automatic transfer switches associated with a first power port of said multiple power ports.

24. A system for supplying power to electronic equipment, comprising:
a piece of electronic equipment including multiple internal power supplies, each said internal power supply being associated with a power port for receiving power from an external source;
an automatic transfer switching system, separate from said piece of electronic equipment, for receiving input power from first and second power sources and selectively providing output power to a load via one or more output ports; and
power cords connecting a plurality of said power ports of said piece of electronic equipment to said one or more output ports of said automatic transfer switching system.

25. The system of claim 24, wherein said piece of electronic equipment has a first number, M, of said internal power supplies and requires a second number, N, of said internal power supplies to be operative for supplying power for said piece of electronic equipment to be fully functional, where N is greater than M/2.

26. The system of claim 25, wherein M is at least six and N is at least five.

27. The system of claim 24, wherein said automatic transfer switching system is operative for switching from outputting power from said first power source to outputting power from said second power source responsive to one of a power signal degradation and a power signal interruption of a first power signal of said first power source.

28. The system of claim 24, wherein said automatic transfer switching system comprises multiple automatic transfer switches, each of said multiple automatic transfer switches being operative for receiving input power from said first and second power sources and selectively providing output power to a load via one or more output ports.

29. The system of claim 28, wherein a number of said multiple automatic transfer switches is at least equal to a number of said plurality of said power ports of said piece of electronic equipment.

30. The system of claim 29, wherein said number of said plurality of power ports of said piece of electronic equipment is equal to a number of said multiple internal power supplies.

31. The system of claim 28, wherein said multiple automatic transfer switches are interconnected to form a power tray.

32. The system of claim 31, wherein said power tray has a dimension of no more than 2 U's.

33. The system of claim 31, wherein said power tray has a dimension of no more than 1 U.

34. The system of claim 31, wherein each of said automatic transfer switches has one or more visual indicators on a first side thereof and said automatic transfer switches are interconnected such that said first sides of said automatic transfer switches are offset from one another.

35. The system of claim 34, wherein said automatic transfer switches are interconnected to form a wedge shape.

36. The system of claim 31, wherein said piece of electronic equipment and said power tray are disposed in an equipment rack.

37. The system of claim 31, further comprising two pieces of electronic equipment, each including multiple internal power supplies, and two power trays disposed in an equipment rack.

38. The system of claim 37, wherein said two power trays occupy a space of no more than 2 U's in said equipment rack.

39. The system of claim 37, wherein said two power trays are disposed between said two pieces of electronic equipment in said equipment rack.

40. The system of claim 24, further comprising air-based cooling system for said equipment rack, said air-based cooling system being free of any liquid coolants at said equipment rack.

41. The system of claim 40, wherein said air-based cooling system provides different airflows at different locations of said equipment rack.

42. The system of claim 40, wherein said air-based cooling system further comprises multiple valves for controlling said airflows based on a control signal.

43. The system of claim 42, wherein said control signal is based on information from a sensor disposed in said equipment rack, said sensor operative for sensing one of a temperature, a pressure, and a power usage in said equipment rack.

44. The system of claim 24, further comprising a power distribution system interposed between said automatic transfer switching system and said first and second power sources.

45. The system of claim 24, further comprising multiple power distribution system devices associated with a first power port of said multiple power ports.

46. The system of claim 24, further comprising multiple automatic transfer switches associated with a first power port of said multiple power ports.

47-74. (canceled)
